(19) United States
(12) Patent Application Publication
(10) Pub. No.: US 2011/0031467 A1
(43) Pub. Date: Feb. 10, 2011

(54) INFORMATION RECORDING AND REPRODUCING APPARATUS

(75) Inventors: Koichi KUBO, Yokohama-shi (JP); Mitsuru Sato, Kuwana-shi (JP); Chikayoshi Kamata, Kawasaki-shi (JP); Noriko Bota, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/849,319

(22) Filed: Aug. 3, 2010

(30) Foreign Application Priority Data
Aug. 5, 2009 (JP) 2009-182131

(51) Int. Cl. H01L 45/00

(52) U.S. Cl. 257/5; 257/2; 257/E45.001

(57) ABSTRACT

An information recording and reproducing apparatus according to an embodiment has a memory cell including a recording layer operative to change in a reversible manner between a first state having a certain resistance value upon application of a voltage pulse and a second state having a resistance value higher than that of the first state. The recording layer includes a first compound layer represented by a composition formula of AₓM_{y}X₄ (0.1≦x≦1.2, 2<y≦2.9). The A is at least one element selected from a group of Mn (manganese), Fe (iron), Co (cobalt), Ni (nickel), and Cu (copper). The M is at least one element selected from a group of Al (aluminum), Ga (gallium), Ti (titanium), Ge (germanium), and Sn (tin). The X is O (oxygen).

### CROSS-REFERENCE TO RELATED APPLICATIONS

This application is based upon and claims the benefit of priority from the prior Japanese Patent Application No. 2009-182131, filed on Aug. 5, 2009, the entire contents of which are incorporated herein by reference.

### BACKGROUND

1. Field

Embodiments relate to information recording and reproducing apparatuses.

2. Description of the Related Art

With the global proliferation of the portable equipment as well as tremendous evolution in high-speed information transmission networks, there is a rapidly increasing demand for small, large capacity non-volatile memory devices. Particularly, NAND-type flash memory and mini-HDD (Hard Disk Drive) have rapidly improved in their recording density, and now constitute a large market.

Under these circumstances, some ideas of new memory have been proposed for further improvements in recording density. For example, PRAM (Phase Change Memory) uses a material that can take two states of amorphous state (off) and crystalline state (on) as a recording material. These two states correspond to binary data “0” or “1” to record data.

For write/erase operations, for example, an amorphous state is established by applying a high-power pulse to the recording material, while a crystalline state is established by applying a low-power pulse to the recording material.

For a read operation, reading is performed by causing a so small read current to flow through the recording material that will not cause write/erase, and then measuring the electrical resistance of the recording material. The recording material in an amorphous state has a larger resistance value than that of a crystalline state, the difference of which is by a factor of about 10³.

Such memory has also been reported that utilizes a principle of changing a resistance different from that of PRAM. For example, one non-volatile memory uses a memory cell with a recording layer having a high-resistance film and an ion source layer. Another memory utilizes a memory cell with a resistive element having a conductor film and an insulator film. These non-volatile memory devices utilize ions. Specifically, the resistance value of the memory element varies due to ionization of metallic elements or transfer of ionized metallic elements. Each ion source layer of the former non-volatile memory contains one or more elements (metallic elements) selected from Ag (silver), Cu (copper), or Zn (zinc), and one or more elements (chalcogenide elements) selected from S (sulfur), Se (selenium), or Te (tellurium). A conductor film of the latter non-volatile memory may be formed of a metal film containing one or more metallic elements selected from Cu, Ag, Zn and the like. Alternatively, it may be formed of an alloy film (e.g., CuTe) or a metallic compound film, containing the same.

It is desirable to improve recording density and to reduce power consumption for practical use of the non-volatile memory with the above-described memory cells.

### BRIEF DESCRIPTION OF THE DRAWINGS

FIG. 1 is a conceptual diagram describing a basic principle for recording/reproducing information in an information recording and reproducing apparatus according to an embodiment;

FIG. 2 is a graph illustrating a relation between the Al/Mn ratio and voltage margin where the compound of the recording layer illustrated in FIG. 1 is MnₓAl_{y}X₄;

FIG. 3 is a graph illustrating a relation between x and y and the cycle life of a memory cell where the compound of the recording layer illustrated in FIG. 1 is AₓM_{y}X₄;

FIG. 4 is a schematic diagram illustrating a structure of a recording part of a memory cell in the information recording and reproducing apparatus according to the embodiment;

FIG. 5 is a schematic diagram illustrating a specific example where sets of first compound layers 12A and second compound layers 12B are alternately laminated, each set being included in a respective recording layer 12;

FIG. 6 is a schematic diagram illustrating probe memory with memory cells according to the embodiment;

FIG. 7 is a schematic diagram illustrating the same probe memory;

FIG. 8 is a conceptual diagram describing a condition during a recording operation (set operation) in the same probe memory;

FIG. 9 is a schematic diagram describing a recording operation performed in the same probe memory using the recording part illustrated in FIG. 1;

FIG. 10 is a schematic diagram describing a reproducing operation performed in the same probe memory using the recording part illustrated in FIG. 1;

FIG. 11 is a schematic diagram describing a recording operation performed in the same probe memory using the recording part illustrated in FIG. 4;

FIG. 12 is a schematic diagram describing a reproducing operation performed in the same probe memory using the recording part illustrated in FIG. 4;

FIG. 13 is a schematic diagram illustrating cross-point type semiconductor memory with memory cells according to the embodiment;

FIG. 14 is a schematic diagram illustrating a structure of a memory cell array part of the same cross-point type semiconductor memory;

FIG. 15 is a schematic diagram illustrating an exemplary structure of a memory cell in the same cross-point type semiconductor memory;

FIG. 16 is a schematic diagram illustrating another structure of a memory cell array in the same cross-point type semiconductor memory;

FIG. 17 is a schematic diagram illustrating a still another structure of a memory cell array in the same cross-point type semiconductor memory;

FIG. 18 is a schematic cross-sectional view of a memory cell in flash memory with a memory cell according to the embodiment;

FIG. 19 is a circuit diagram of a NAND cell unit with the memory cell illustrated in FIG. 18;

FIG. 20 is a schematic diagram illustrating a structure of the NAND cell unit with the memory cell illustrated in FIG. 18;

FIG. 21 is a schematic diagram illustrating NAND-type flash memory with normal MIS transistors as select gate transistors;

FIG. 22 is a schematic diagram illustrating a variation of the NAND-type flash memory according to the embodiment;

FIG. 23 is a circuit diagram of a NOR cell unit with the memory cell illustrated in FIG. 18;

FIG. 24 is a schematic diagram illustrating a structure of the NOR cell unit with the memory cell illustrated in FIG. 18;

FIG. 25 is a circuit diagram of a 2-transistor type cell unit with the memory cell illustrated in FIG. 18;

FIG. 26 is a schematic diagram illustrating a structure of the 2-transistor type cell unit with the memory cell illustrated in FIG. 18; and

FIG. 27 is a schematic diagram illustrating 2-transistor type flash memory with normal MIS transistors as select gate transistors.

### DETAILED DESCRIPTION

An information recording and reproducing apparatus according to an embodiment comprises: a memory cell including a recording layer operative to change in a reversible manner between a first state having a certain resistance value upon application of a voltage pulse and a second state having a resistance value higher than that of the first state. The recording layer includes a first compound layer represented by a composition formula of AₓM_{y}X₄ (0.1≦x≦1.2, 2<y≦2.9). The A is at least one element selected from a group of Mn (manganese), Fe (iron), Co (cobalt), Ni (nickel), and Cu (copper). The M is at least one element selected from a group of Al (aluminum), Ga (gallium), Ti (titanium), Ge (germanium), and Sn (tin). The X is O (oxygen).

A non-volatile information recording and reproducing apparatus according to this embodiment will now be described in detail below with reference to the accompanying drawings.

[Basic Principles]

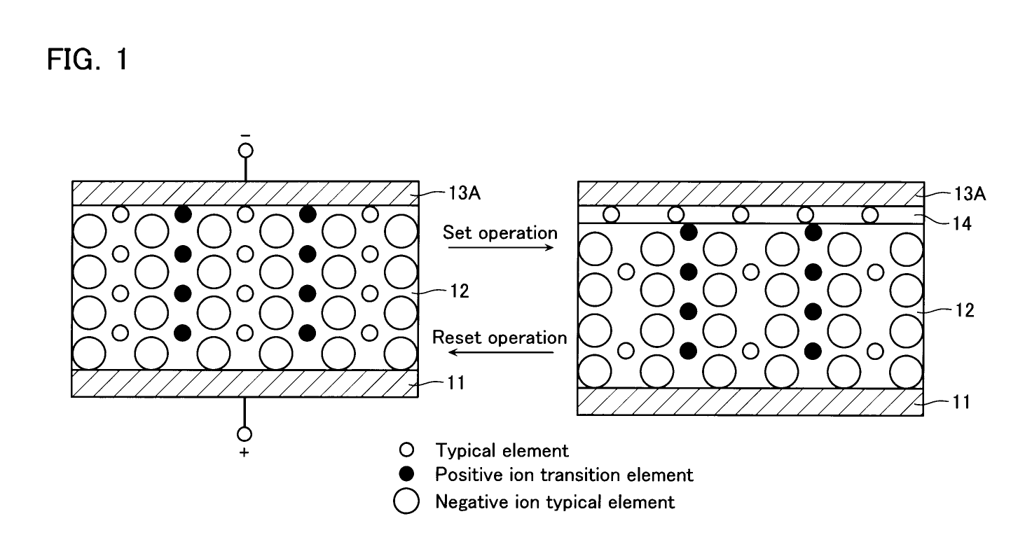

FIG. 1 is a conceptual diagram describing a basic principle for recording/reproducing information in an information recording and reproducing apparatus according to this embodiment.

A recording part of a memory cell for use in the information recording and reproducing apparatus has a structure with a recording layer 12 sandwiched between electrode layers 11 and 13A on each end. The electrode layers 11 and 13A are provided for electrically connecting the recording layer 12 (first compound layer). Note that the electrode layers 11 and 13A may also function as barrier layers to prevent, for example, diffusion of elements between the recording layer 12 and the components sandwiching the recording part.

In the recording part illustrated in FIG. 1, a small white circle in the recording layer 12 denotes an A ion (e.g., diffuse ion), a small black circle denotes an M ion (e.g., host ion), and a large white circle denotes an X ion (e.g., negative ion), respectively.

While the recording layer 12 may use a material represented by AₓM_{y}X₄, it is particularly preferable to use a material having a spinel structure. A and M are elements that are different from each other. In addition, X is O (oxygen).

A is at least one element selected from the group of Mn (manganese), Fe (iron), Co (cobalt), Ni (nickel), and Cu (copper).

Among others, it is preferable that A is at least one element selected from the group of Mn, Fe, and Co. In this case, an optimum ion radius can be obtained for maintaining a crystalline structure, ensuring a sufficient degree of ion transfer as well.

M is at least one element selected from the group of Al (aluminum), Ga (gallium), Ti (titanium), Ge (germanium), and Sn (tin).

Among others, it is preferable that M is at least one element selected from the group of Al and Ga. In this case, the host structure can be kept stable, allowing stable repetition of switching.

Wherein the numeric range of x and y in AₓM_{y}X₄ can be represented by “0.1≦x≦1.2, 2<y≦2.9”. The lower limit of this numeric range is set such that it may maintain a crystalline structure, while the upper limit is set such that it may control a state of electrons in the crystal.

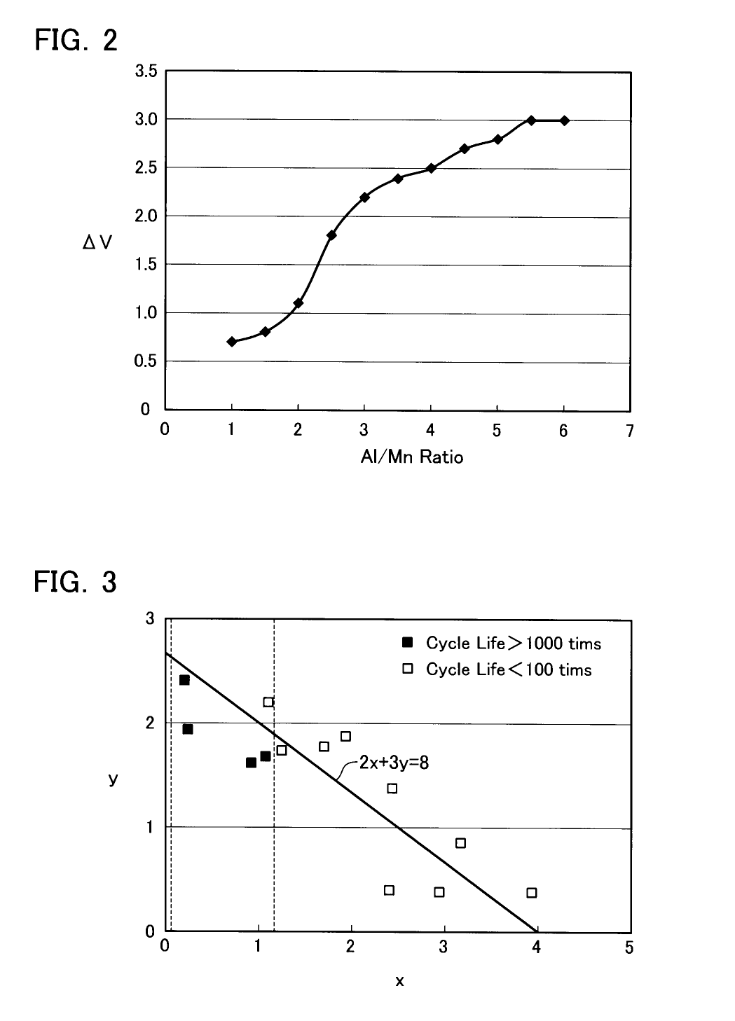

FIG. 2 illustrates a relation between an Al/Mn ratio and a voltage margin ΔV where A is Mn and M is Al. In this graph, an area where the Al/Mn ratio is 3 or more indicates a composition with x less than 1. It can be seen from FIG. 2 that the voltage margin ΔV increases from the vicinity of the point where the Al/Mn ratio is 2. To this extent, it is preferable that y is not less than 2 when x is 1. Thus, the Al/Mn ratio is preferably not less than 2.

FIG. 3 is a graph illustrating a relation between x and y and the number of times that the recording part can be erased (hereinafter, referred to as “cycle life”). In FIG. 3, the solid line is a straight line represented by “2x+3y=8”. Each black square dot in the drawing indicates that the cycle life is larger than 1000 times, while each white square dot indicates that the cycle life is smaller than 100 times. It can be seen from FIG. 3 that black square dot and white square dot are distributed such that they are bounded by the line “2x+3y=8”. This composition “2x+3y>8” indicates the range where the amount of the cation relative to the amount of oxygen is excessive in the spinel structure of MₓAl_{y}O₄, and is the range where it is thought that the spinel structure cannot be maintained. Therefore, it may be considered that the cycle deterioration is caused by the decrease in crystallinity. To this extent, it is preferable that x and y have a relation of “2x+3y≦8” to achieve a larger cycle life.

Additionally, as described above, in order to facilitate distribution of A ions by applying voltage, it is only needed to arrange layers of A ion elements along the direction of connecting the electrodes. For this purpose, with a spinel structure, it is preferable that the “a” axis of the crystal is arranged in parallel to the film surface.

By using the recording layer 12 with such a desired orientation, the recording density of Pbpsi (Peta bits per square inch) class can be principally achieved, and further, lower power consumption can also be achieved.

With the material having the above-described structure, in the case of FIG. 1, two types of positive ion elements are selected such that A ions are easily diffused within the compound of the recording layer 12, while M ions are not diffused within the compound of the recording layer 12. In this case, the compound of the recording layer 12 retains its crystalline structure due to the M ions without diffusion, which may facilitate control of transfer of the A ions. This means that a resistance value of the recording layer 12 can be easily changed.

Here, for the purpose of the following description, consider that a reset state (initial state) denotes a state in which the resistance state of the recording layer 12 is a high resistance state (second state), and a set state denotes a state in which the resistance state of the recording layer is a low resistance state (first state). However, it should be appreciated that this is merely for convenience, and the opposite can also be possible, i.e., a reset state (initial state) represents a low resistance state and a set state represents a high resistance state, depending upon the materials selected, manufacturing methods, or the like. Such a case also falls within the scope of this embodiment.

A potential gradient is generated in the recording layer 12 when voltage is applied to the recording layer 12. Accordingly, some of the A ions travel through the crystal. Therefore, this embodiment utilizes this characteristic to record information. Namely, the recording layer 12 is an insulator (a high-resistance state phase) in its initial state, and the potential gradient then causes a phase change of the recording layer 12, thereby providing the recording layer 12 with conductivity (a low-resistance state phase).

Firstly, for example, such a state is established in which a potential of the electrode layer 13A is relatively low compared to that of the electrode layer 11. Assuming that the electrode layer 11 is at a grounding potential, a negative potential may be applied to the electrode layer 13A.

At this point, some of the A ions in the recording layer 12 move to the side of the electrode layer 13A (cathode), and the A ions in the recording layer (crystal) 12 decreases relative to the X ions. Upon receipt of electrons from the electrode layer 13A, the A ions moved to the side of the electrode layer 13A precipitate as an A atom of a metal to form a metal layer 14. Thus, at a region close to the electrode layer 13A, the A ions are reduced to behave in a metallic manner, which leads to a significant reduction in the electrical resistance of the electrode layer 13A.

Alternatively, when the crystalline structure of the recording layer 12 has cavity sites that can be occupied by the A ions, as the spinel structure or the like does, the A ions that have moved to the side of the electrode layer 13A may fill the cavity sites at the side of the electrode layer 13A. Also in this case, the A ions receive electrons from the electrode layer 13A, and neutrality of charges are locally obtained. Accordingly, the recording layer 12 around the A ions behaves like metal.

The X ions become excessive in the recording layer 12, which results in an increase in the valence of the A ions or M ions left in the recording layer 12. At this moment, if the A ions or M ions are selected such that the electrical resistance is reduced, then the recording layer 12 and the metal layer 14 have lower electrical resistances due to transfer of the A ions, respectively. Thus, the entire recording layer changes to a low-resistance state phase. That is, the recording of information (set operation) completes.

The above process is a kind of electrolysis. That is, it can be considered that an oxidizing agent is generated due to electrochemical oxidization at the side of the electrode layer (anode) 11, while a reducing agent is generated by electrochemical reduction at the side of the electrode layer (cathode) 13A.

Thus, in order to return to a high-resistance state phase from a low-resistance state phase, it is sufficient, for example, that the recording layer 12 is Joule-heated by a mass current pulse to promote an oxidization-reduction reaction of the recording layer 12. That is, due to the Joule heat caused by a mass current pulse, the A ions return to the recording layer 12 with a more thermally stable crystalline structure, after which an initial high-resistance state phase emerges (reset operation).

Alternatively, the reset operation may also be performed by applying a voltage pulse in a reverse direction to that used in the set operation. Namely, as in the set operation, the electrode layer 11 is set at a fixed potential. For example, when the electrode layer 11 is set at a ground potential, a positive potential may be applied to the electrode layer 13A. An A atom close to the electrode layer 13A becomes an A ion as it yields electrons to the electrode layer 13A. Then, it returns into the crystalline structure 12 due to a potential gradient in the recording layer 12. Consequently, the valence of some of the A ions with increased valence decrease to the same number as their initial states, and these A ions change to the initial high-resistance state phase.

However, in order to practically use this principle of operation, it must be verified that no reset operation occurs at room temperature (a sufficiently long retention time is allocated) and that power consumption of the reset operation is sufficiently small.

The former requirement (allocation of a sufficient retention time) can be met by reducing the coordination number of A ion (ideally, to 2 or less), or by setting the valence thereof equal to or greater than 2, or alternatively, by increasing the valence of X ion (ideally, to 3 or more). If the valence of A ion is equal to 1 as in Cu ion, then the A ion cannot obtain a sufficient ion transfer resistance in a set state, and hence immediately returns into the recording layer 12 from the metal layer 14. In other words, a sufficiently long retention time cannot be allocated. However, if the valence of A ion is equal to or greater than 3, then a larger voltage is required for a set operation, which may cause crystal destruction. After all, it is preferable for the information recording and reproducing apparatus to set the valence of A ion equal to 2.

The latter requirement (lower power consumption in reset operation) may be satisfied by employing such a structure where an ion radius of an A ion is optimized so that the A ion is allowed to travel through the recording layer (crystal) 12 and hence a transfer path for the A ion is provided, while setting the valence of the A ion equal to or less than 2 so as not to cause crystal destruction. Such a recording layer 12 may be obtained by employing the elements and crystalline structures described. This means that a material with a spinel structure represented by AₐM_{y}X₄ (0.1≦x≦1.2, 2<y≦2.9) may be employed for the recording layer 12. In this case, A and M are elements that are different from each other, and X is O. In addition, A is at least one element selected from the group of Mn, Fe, Co, Ni, and Cu, while M is at least one element selected from the group of Al, Ga, Ti, Ge, and Sn.

On the other hand, reproduction of information may be easily performed by, for example, applying a voltage pulse to the recording layer 12 and detecting a resistance value thereof. However, it is necessary that the voltage pulse has a so small amplitude that would not cause transfer of A ions.

Optimum values of mixing ratio of atoms will now be described below.

If there are cavity sites that can be occupied by A ions, or if A ions can occupy any sites which is originally occupied by M ions, mixing ratios of A ions can be determined within a certain range. Furthermore, the mixing ratio of A ions and M ions also differs from that of stoichiometric composition if there is an excess/deficiency of X ions. Accordingly, in an actual recording layer 12, the mixing ratio of A ions and M ions maybe determined within a certain range. This may optimize the mixing ratio of A ions so that appropriate resistance values of the recording layer 12 in each state or appropriate diffusion coefficients of A ions can be obtained.

The lower limit of the mixing ratio of A ions and M ions is set so that a compound having a desired crystalline structure can be fabricated with ease. In addition, if a total amount of ions that occupy the sites of M ions is too small, it is difficult to keep the structure stable after A ions are extracted.

As described above, according to this embodiment, using the material mentioned above for the recording layer 12 not only may facilitate diffusion of positive ions, but also reduce the power consumption required for resistance change, improving heat stability. In addition, operational properties may be easily controlled since a resistance change can be caused by means of only diffusion of positive ion elements in a crystalline structure. This may reduce the variation of operational properties among memory cells.

Furthermore, the mobility of ions differs between an inside region of the crystalline structure and the circumference of a crystal grain. Thus, in order to provide uniform recording/erasing properties among memory cells by means of transfer of diffuse ions inside the crystalline structure, it is preferable that the recording layer 12 is in a polycrystalline or monocrystalline state. If the recording layer 12 is in a polycrystalline state, it is then preferable that, in view of ease of film formation, a crystal grain has an average size of not less than 3 nm in the direction of the cross-section of the recording layer 12 according to a distribution having a single peak. Note that if the average size is 5 nm or more, the film formation may be even easier. Furthermore, if the average size is 10 nm or more, more uniform recording/erasing properties may be obtained among those memory cells located at different positions.

In the meantime, since an oxidizing agent is generated at the side of the electrode layer (anode) 11 after a set operation, it is preferable that the electrode layer 11 comprises a material which is difficult to oxidize (e.g., electrically conductive nitride, electrically conductive oxide, and so on).

It is also preferable that the electrode layer 11 comprises a material without ion conductivity. Such a material includes the following materials (1)-(4).

(1) MNₓ

M is at least one element selected from the group of Ti, Zr (zirconium), Hf (hafnium), V (vanadium), Nb (niobium), Ta (tantalum), and W (tungsten). N is nitrogen, and x is “0.5≦x≦2”.

(2) MOₓ

M is at least one element selected from the group of Ti, V, Cr (chromium), Mn, Fe, Co, Ni, Cu, Zr, Nb, Mo (molybdenum), Ru (ruthenium), Rh (rhodium), Pd (palladium), Ag, Hf, Ta, W (tungsten), Re (rhenium), Ir (iridium), Os (osmium), and Pt (platinum). Consider that x satisfies “1≦x≦4”.

(3) AMO₃

A is at least one element selected from the group of La (lanthanum), K (potassium), Ca (calcium), Sr (strontium), Ba (barium), and Ln (lanthanoid). M is at least one element selected from the group of Ti, V, Cr, Mn, Fe, Co, Ni, Cu, Zr, Nb, Mo, Ru, Rh, Pd, Ag, Hf, Ta, W, Re, Ir, Os, and Pt. O is oxygen.

(4) A₂MO₄

A is at least one element selected from the group of K, Ca, Sr, Ba, and Ln (lanthanoid). M is at least one element selected from the group of Ti, V, Cr, Mn, Fe, Co, Ni, Cu, Zr, Nb, Mo, Ru, Rh, Pd, Ag, Hf, Ta, W, Re, Ir, Os, and Pt. O is oxygen.

Among these, LaNiO₃ (nickel lanthanum oxide) may be considered to be the most desirable material from the viewpoint of comprehensive performance, taking into account the better electrical conductivity, and so on.

In addition, since a reducing agent will be generated at the side of the protection layer (cathode) 13A after a set operation, it is desirable that the protection layer (electrode layer) 13A has a function for preventing the recording layer 12 from reacting with atmosphere.

Such a material includes a semiconductor, such as amorphous carbon, diamondlike carbon, or SnO₂ (tin oxide).

The electrode layer 13A may function as a protection layer for protecting the recording layer 12, or a protection layer may be provided instead of the electrode layer 13A. In this case, such a protection layer may be an insulator or a conductor.

In addition, in order to efficiently heat the recording layer 12 in a reset operation, a heater layer (a material with a resistivity of about 10⁻⁵ Ωcm or more) may be provided at the cathode side, in this example, at the side of the electrode layer 13A.

Other specific examples of the recording layer 12 will now be described below.

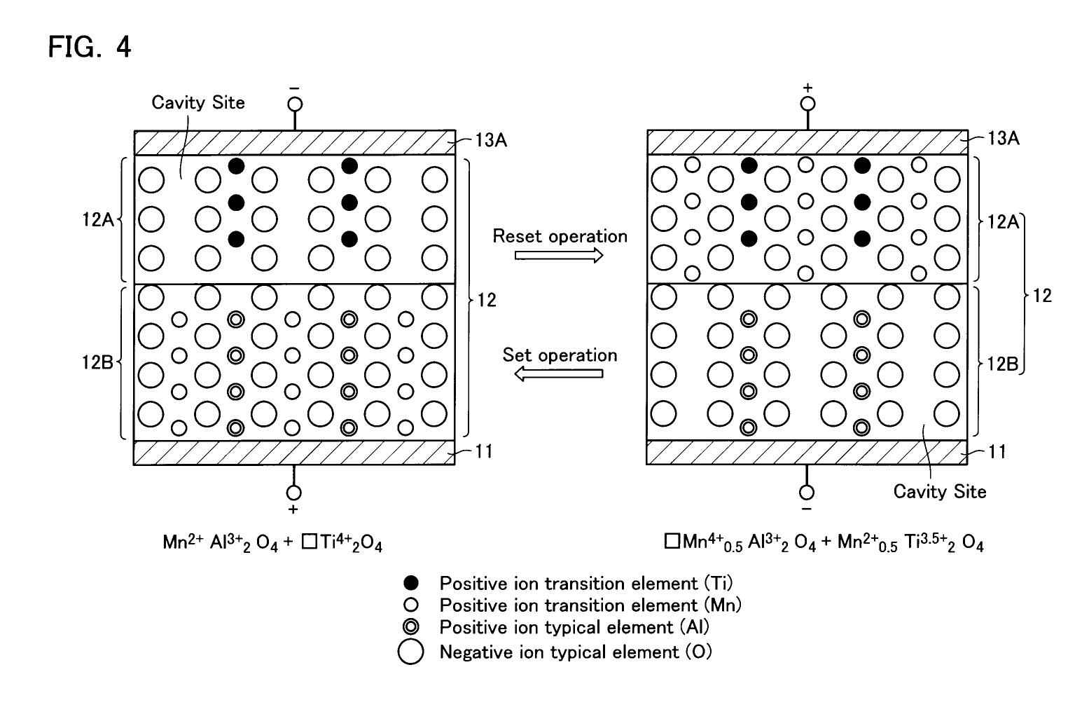

FIG. 4 is a schematic diagram illustrating a structure of a recording part of the information recording and reproducing apparatus according to the embodiment.

This recording part also has a structure with the recording layer 12 sandwiched between the electrode layers 11 and 13A.

In the recording part illustrated in FIG. 4, a small white circle in a first compound layer 12A denotes an A ion (e.g., diffuse ion), a small thick white circle in the first compound layer 12A denotes an M1 ion (e.g., host ion), a large white circle in the first compound layer 12A denotes an X1 ion (e.g., negative ion), respectively. Additionally, in the recording part illustrated in FIG. 4, a double circle in a second compound layer 12B denotes an M2 ion (e.g., transition element ion), and a large white circle in the second compound layer 12B denotes an X2 ion (e.g., negative ion), respectively.

Also in the recording part of FIG. 4, as described in detail below, voltage is applied between the electrode layers 11, 13A and the recording layer 12 to cause a phase change in the recording layer 12. As a result, the resistance value of the recording layer 12 is changed to record information.

The recording layer 12 has a first compound 12B which is arranged at the side of the electrode layer 11, and a second compound 12A which is arranged at the side of the electrode layer 13A and in contact with the first compound 12A.

The first compound 12A comprises a compound having at least two types of positive ion elements. Specifically, it is denoted by AₓM1_{y}X1_{z}. At least one type of the positive ion elements of the first compound 12A is a transition element having a d orbit incompletely filled with electrons.

As in FIG. 1, if the first compound 12A has a spinel structure represented by AₓM1_{y}X1₄ (0.1≦x≦1.2, 2<y≦2.9), then A ions easily travel through the compound. Thus, the first compound 12A having a spinel structure is suitable for the material of the recording layer 12.

It is particularly preferable that the first compound 12A is oriented so that its transfer path is arranged in the direction of connecting the electrodes. This facilitates transfer of A ions within the first compound 12A. Furthermore, it is preferable that the first compound 12A has a lattice constant consistent with that of the second compound 12B. In this case, the orientation of the material may be easily controlled to form a film of the compound 12, if such a material is used that is difficult to form a film due to the existence of cavity sites.

The second compound 12B has a transition element having a d orbit incompletely filled with at least one type of electron. The second compound 12B also has cavity sites that can accommodate A ion elements diffused from the first compound 12A. However, some or all of the cavity sites may accommodate A ion elements transitioned from the first compound 12A. Note that some of the cavity sites may be occupied by other ions in advance in order to facilitate film formation of the second compound 12B.

In addition, the second compound 12B has a resistivity which is not more than that of the first compound 12A in a low resistance state, desirably not more than 10⁻¹ Ωcm, in both cases when the recording layer 12 is in a low resistance state and when it is in a high resistance state.

A specific example of the second compound 12B includes, for example, a compound represented by the following chemical formula. Here, “*” in the following formula denotes a cavity site.

*_{α}A₁₋ₓX₂₋ᵤ (1)

A is at least one element selected from the group of Ti, Zr, Hf, and Sn. X is at least one element selected from the group of O (oxygen), N (nitrogen), and F (fluorine). α satisfies “0.3<α≦2”, x of “1-x” satisfies “0.001<x≦0.2”, and u of “2-u” satisfies “0≦u<0.2”.

*_{β}A_{2-y}X₃₋ᵥ (2)

A is at least one element selected from the group of V, Nb, Ta, Cr, Mo, W, Mn, Fe, Co, Ga, and In (indium). X is at least one element selected from the group of O, N, and F. β satisfies “0.3<β≦2”, y of “2-y” satisfies “0.001<y≦0.2”, and v of “3-v” satisfies “0≦v<0.3”.

*_{γ}A_{2-z}X_{5-w} (3)

A is at least one element selected from the group of V, Nb, and Ta. X is at least one element selected from the group of N and F. γ satisfies “0.3<γ≦2”, z of “2-z” satisfies “0.001<z≦0.2”, and w of “5-w” satisfies “0≦w<0.5”.

Preferably, the second compound 12B has any one of the structures including spinel, corundum, rutile, ramsdellite, anatase, hollandite, brookite, and pyrolusite structures.

In order to achieve low power consumption, it is important to utilize such a structure where an ion radius of an A ion is optimized so that the A ion is allowed to travel through a crystal without causing crystal destruction, and hence a transfer path for the A ion is provided.

This condition may be satisfied by using the above-described material and crystalline structure for the second compound 12B, which is effective for achieving low power consumption.

In addition, a Fermi level of electrons of the first compound layer 12A is lower than that of electrons of the second compound layer 12B. This is one of desirable conditions that cause the recording layer 12 to have revesibility. Any of the Fermi levels used here is obtained as a value measured from a vacuum level.

In order to further increase the resistance value of the recording layer 12 when the corresponding memory cell is in a reset state, an insulator with permeability to ions emitted from the first compound 12A and having a thickness of on the order of several nm may also be inserted between the first compound 12A and the second compound 12B in the recording layer 12 formed as described above. This insulator is a compound including at least an A ion element emitted from the first compound 12A and other typical elements, and preferably, is a complex oxide.

A preferable range of film thicknesses of the second compound 12B will now be described below.

In order to obtain an accommodation effect of A ions within cavity sites, it is preferable that the second compound 12B has a film thickness of 1 nm or more.

On the other hand, if the number of cavity sites in the second compound 12B is larger than the number of A ions in the first compound 12A, the resistance change effect of the second compound 12B would be reduced. Thus, it is preferable that the number of cavity sites in the second compound 12B is equal to or less than the number of A ions in the first compound 12A within the same cross-sectional area.

The density of the A ions in the first compound 12A is approximately the same as that of the cavity sites in the second compound 12B. Thus, it is preferably that the film thickness of the second compound 12B is equal to or less than that of the first compound 12A.

Generally, a heater layer (a material with a resistivity of about 10⁻⁵ Ωcm or more) may be provided at the cathode side to further facilitate a reset operation.

For probe memory, since a reducing material precipitates at the cathode side, it is preferable to provide a surface protection layer to prevent reaction of the material with atmosphere.

The heater layer and the surface protection layer may be formed of one material having functions of both of heating and surface protection. For example, semiconductor, such as amorphous carbon, diamondlike carbon, or SnO₂ has both the heating and surface-protecting functions.

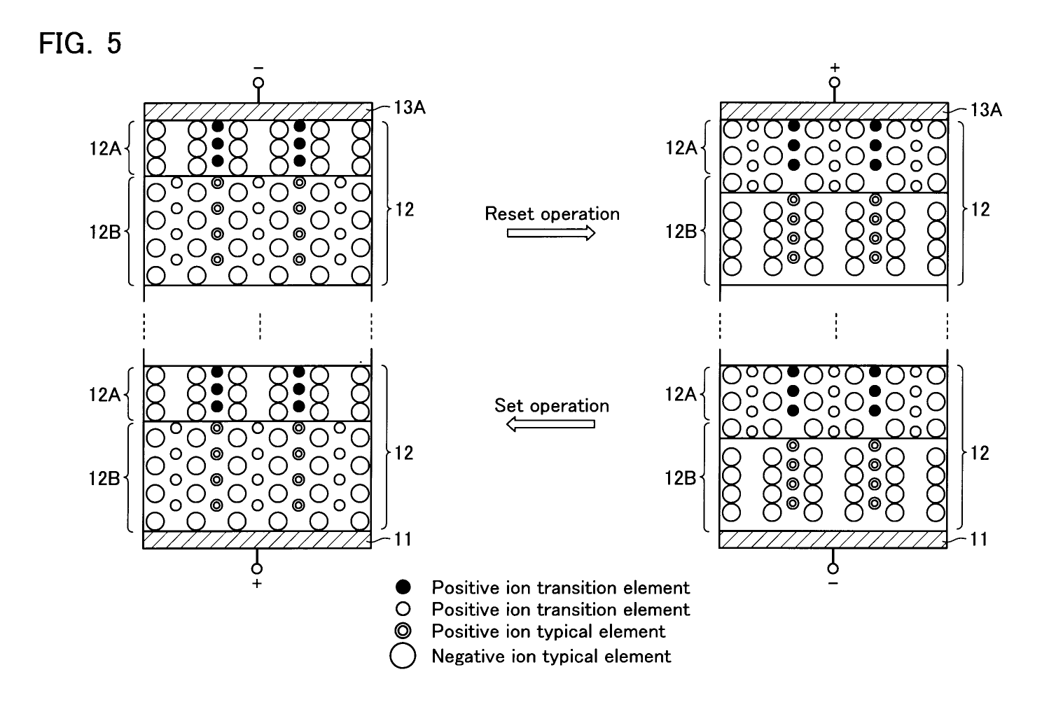

Note that, as illustrated in FIG. 5, the recording layer 12 may have such a structure having a plurality of first compound layers 12A and second compound layers 12B alternately and repeatedly laminated.

Operational principles of the recording part illustrated in FIG. 4 will now be described below.

As with the recording part of FIG. 1, the recording part illustrated in FIG. 4 also records information by causing the recording layer 12 to be an insulator (a high resistance state phase) in an initial state, and causing a phase change in the recording layer 12 due to a potential gradient to provide the recording layer 12 with conductivity (a low-resistance state phase).

In this recording part, potentials are applied to the electrode layers 11 and 13A so that the first compound layer 12A becomes the anode side and the second compound layer 12B becomes the cathode side, and a potential gradient is caused in the recording layer 12. Then, some of the A ions in the first compound layer 12A containing a first compound travel through a crystal and enter the second compound layer 12B at the cathode side.

Since there are cavity sites of A ions in the crystal of the second compound layer 12B, those A ions transferred from the first compound layer 12A containing the first compound are accommodated within the cavity sites.

The second compound layer 12B involves a relatively large proportion of positive ions compared to negative ions. That is, the chemical equivalent (mole number multiplied by valence) of positive ions is larger than that of negative ions. Thus, the second compound 12B receives electrons from the cathode to maintain its electrical neutrality. This results in a decrease in the valence of some of the A ions in the second compound 12B, and the second compound 12B becomes a less oxidized compound.

Conversely, the first compound layer 12A involves a relatively small proportion of positive ions compared to negative ions. That is, the chemical equivalent of positive ions is smaller than that of negative ions. Thus, the first compound 12A emits electrons to the anode side to maintain its electrical neutrality. This results in an increase in the valence of some of the A ions in the first compound 12A, and the first compound 12A becomes a more oxidized compound.

Namely, some of the A ions in the first compound layer 12A transfer into the second compound layer 12B, assuming that the first compound layer 12A and the second compound layer 12B are in high resistance states (insulators) during their reset states (initial states). Thus, conductive carriers are produced in the crystals of the first compound layer 12A and the second compound layer 12B, and both of compound layers 12A and 12B have electrical conductivity. At this point, however, if a material having a composition ratio such as AₓM_{y}X₄ (0.1≦x≦1.2, 2<y≦2.9) (where A is Mn, Fe, or Co; M is Al or Ga) is employed as the material of the recording layer 12, it is expected that the voltage margin would increase for the following reasons. During a set operation, some of A ions are believed to transfer outside the crystal. At this point, M_{y}Oₓ serves to form a crystalline framework of the compound layer 12 and prevent crystal destruction thereof. A composition range of AₓM_{y}X₄ is limited to “0.1≦x≦1.2, 2<y≦2.9”. By doping an excessive M than required, the excessive M ions are incorporated into A sites. The M ions are more difficult to transfer as compared with the A ions due to their higher valence, causing an effect to increase the transfer resistance of the A ions. This results in an increase in set voltage. In contrast, during a reset operation, a strong attractive interaction occurs between A ions with larger valence and the crystal. Accordingly, any increase in transfer resistance is compensated with the attractive interaction, without causing a significant increase in voltage. Rather, this would result in an increase in voltage margin. Note that it is desirable that x and y satisfy “2x+3y≦8” (see FIG. 3) in order to ensure a sufficient cycle life.

In the meantime, after completion of a set operation, an oxidizing agent is generated at the anode side. Therefore, it is desirable that such a material is used for the electrode layer 11 that is difficult to oxidize and does not have ion conductivity (e.g., electrically conductive oxide). Preferred examples of this material are described above.

A reset operation (erasing) may be carried out by promoting a phenomenon that the A ions previously accommodated within the cavity sites of the second compound layer 12B return into the first compound layer 12A by heating the recording layer 12, as described above.

Specifically, the recording layer 12 may easily return to its original high resistance state (insulator) by means of a Joule heat generated by amass current pulse applied to the recording layer 12 as well as the residual heat. Since the recording layer 12 is in a low resistance state, a mass current still flows through the recording layer 12 even if there is only a low potential difference.

In this way, a mass current pulse is applied to the recording layer 12 to elevate the electrical resistance value of the recording layer 12, thereby a reset operation being achieved. This is, due to heat energy, the recording layer 12 returns, from a high-energy metastable state obtained by the set operation, to a low-energy stable state or a state of insulator which the recording layer 12 has before the set operation. Alternatively, a reset operation may also be achieved by applying an electrical field in the opposite direction to that in the set operation.

In turn, a reproducing operation may be easily carried out by causing a current pulse to flow through the recording layer 12 and detecting a resistance value of the recording layer 12. However, it is necessary that the current pulse has a so small value that would not cause a change in resistance of the material included in the recording layer 12.

However, a voltage margin when atypical resistive material such as NiO (nickel oxide) is used is approximately 1 V to 2 V, which is not sufficient. Therefore, there is a need for a larger voltage margin for further reduction in malfunction probability.

To this extent, this embodiment may achieve an increase in voltage margin by using the above-described material for the recording layer 12. This may provide an information recording and reproducing apparatus that can operate in a stable manner.

[Applications]

Next, the information recording and reproducing apparatus in which the recording parts illustrated in FIGS. 1 and 4 are implemented will be described below.

In the following description, three cases will be given: where the recording part illustrated in FIGS. 1 to 3 is implemented in probe memory; where the recording part is implemented in semiconductor memory; and where the recording part is implemented in flash memory.

[Application 1: Probe Memory]

(Probe Memory Configuration)

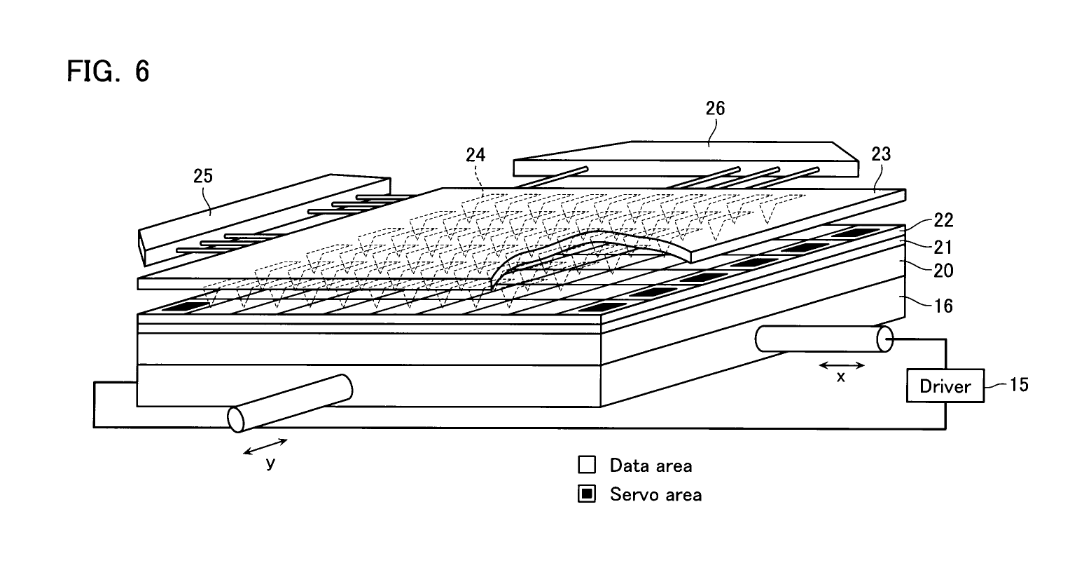

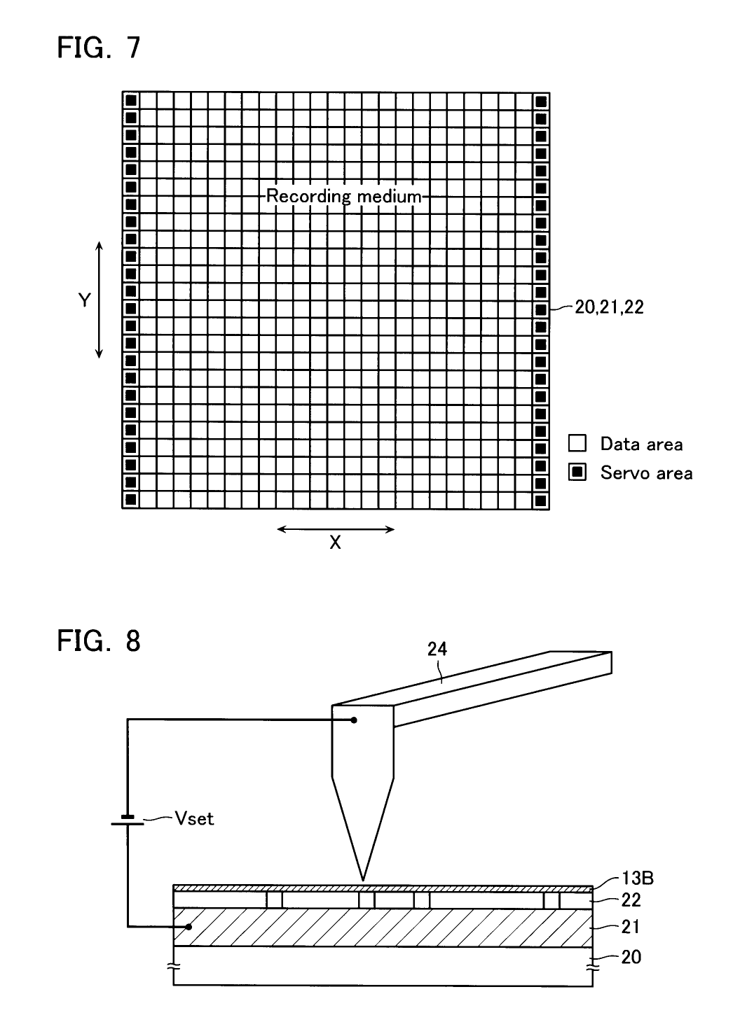

FIGS. 6 and 7 are schematic diagrams illustrating a general configuration of probe memory in which the recording parts illustrated in FIGS. 1 and 4 are implemented.

As illustrated in FIG. 6, a recording medium provided with the recording part of this embodiment is arranged on an XY scanner 16. A probe array is arranged opposite to the recording medium.

The probe array has a substrate 23 and a plurality of probes (heads) 24 that are arranged in a matrix form on the bottom surface of the substrate 23. Each of the probes 24 includes, e.g., a cantilever, and is driven by multiplex drivers 25 and 26.

Operations of the XY scanner 16 so configured will now be described below. While a plurality of probes 24 can operate individually via respective microactuators in the substrate 23, by way of illustration, consider here that all of the microactuators carry out a same operation at a time to access a data area of the recording medium.

Firstly, all of the probes 24 are reciprocated at a constant cycle in the X direction by using the multiplex drivers 25 and 26, and position information in the Y direction is read from a servo area of the recording medium. The position information in the Y direction is transferred to a driver 15.

Then, based on this position information, the driver 15 drives the XY scanner 16, moves the recording medium in the Y direction, and positions the recording medium and the probes 24.

Subsequently, after completion of the positioning of the recording medium and the probes 24, a data read or write operation is performed at the same time and continuously using all of the probes 24 on the data areas.

In this case, the probes 24 may successively access those memory cells aligned in the X direction since it is reciprocating in the X direction. Accessing the memory cells one at a time while sequentially changing positions on the recording medium in the Y direction allows the data areas to be accessed on a line-by-line basis.

Note that the recording medium may also be reciprocated at a constant cycle in the X direction to read position information from the recording medium, and the probes 24 may move in the Y direction.

The recording medium includes, for example, a substrate 20, an electrode layer 21 on the substrate 20, and a recording layer 22 on the electrode layer 21.

The recording layer 22 has a plurality of data areas, as well as servo areas arranged at each end in the X direction of the plurality of data areas. The plurality of data areas occupy major parts of the recording layer 22.

A servo burst signal is recorded in a servo area. The servo burst signal indicates position information in the Y direction in a data area.

In addition to these types of information, an address area in which address data is recorded as well as a preamble area for synchronization are further arranged in the recording layer 22.

The data and servo burst signal are recorded in the recording layer 22 as a recording bit (electrical resistance fluctuation). Information of the recording bit, “1” or “0”, is read by detecting an electrical resistance of the recording layer 22.

In this example, one probe (head) is provided for each data area, and one probe is provided for each servo area.

The data area includes a plurality of tracks. A track in a data area is specified by an address signal read from an address area. In addition, the servo burst signal read from a servo area is intended to move the corresponding probe 24 to the center of the track and eliminate read errors of the recording bit.

In this case, it is possible to utilize an HDD head position control technology with the X and Y directions corresponding to a down track direction and a track direction, respectively.

Recording/reproducing operations of this probe memory will now be described below.

(Recording/Reproducing Operations of Probe Memory)

FIG. 8 is a conceptual diagram describing a condition during a recording operation (set operation).

It is intended that the recording medium includes an electrode layer 21 on a substrate (e.g., a semiconductor chip) 20, a recording layer 22 on the electrode layer 21, and a protection layer 13B on the recording layer 22. The protection layer 13B includes, e.g., a thin insulator.

A recording operation is performed by applying voltage to the surface of a recording bit 27 in the recording layer 22 and generating a potential gradient within the recording bit 27. Specifically, a current/voltage pulse may be applied to the recording bit 27.

(Using Recording Part of FIG. 1)

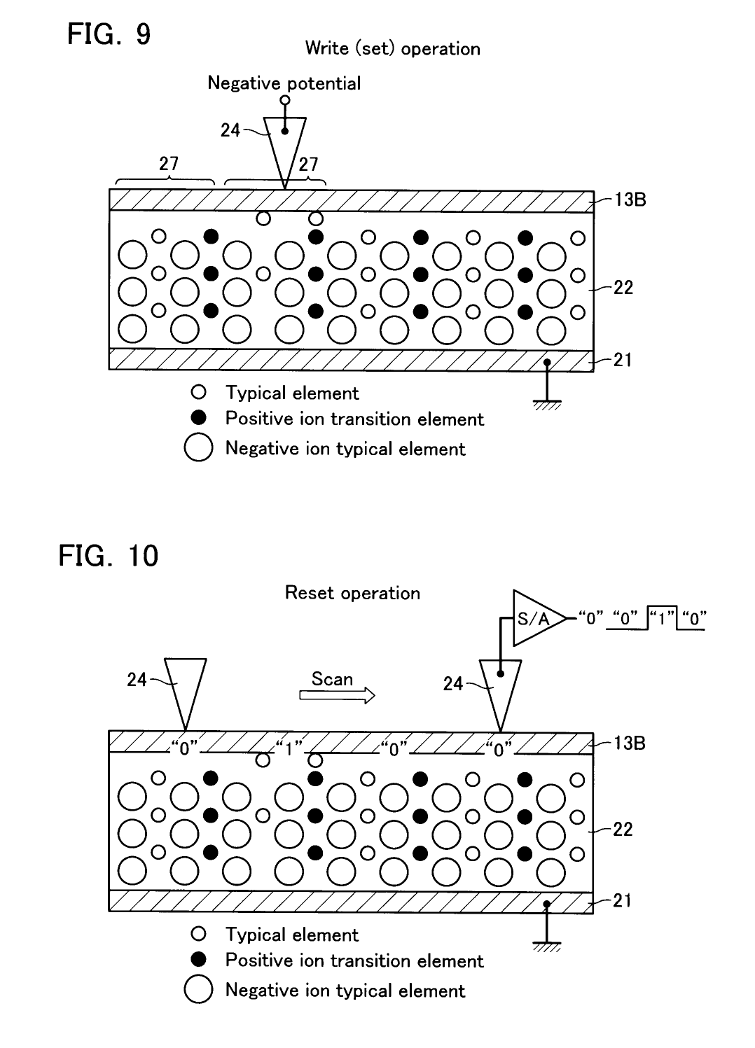

Referring now to FIGS. 9 and 10, recording/reproducing operations using the recording part of FIG. 1 will be described below.

FIG. 9 is a schematic diagram describing a recording operation of the probe memory using the recording part of FIG. 1.

Firstly, as illustrated in FIG. 9, such a state is established in which a potential of a probe 24 is relatively low compared to that of the electrode layer 21. Assuming that the electrode layer 21 is at a fixed potential, e.g., a grounding potential, a negative potential may be applied to the probe 24.

A current pulse is generated by discharging electrons from the probe 24 toward the electrode layer 21 using, for example, an electron generating source or a hot electron source. Alternatively, a voltage pulse may be applied to the probe 24 while the probe 24 comes in contact with the surface of the recording bit 27.

At this point, for example, in the recording bit 27 of the recording layer 22, some of A ions move to the side of the probe (cathode) 24, and the A ions in the crystal decrease relative to the X ions. In addition, the A ions moved to the side of the probe 24 precipitate as a metal upon receipt of electrons from the probe 24.

The X ions become excessive in the recording bit 27, which results in an increase in the valence of the A ions in the recording bit 27. Namely, since the recording bit 27 has electron conductivity due to carrier implantation caused by a phase change, the resistance decreases in the film thickness direction, and the recording operation (set operation) completes.

Note that a current pulse for recording may also be generated by establishing a state in which the potential of the probe 24 is relatively high compared to that of the electrode layer 21.

FIG. 10 is a schematic diagram describing a reproducing operation of the probe memory using the recording part of FIG. 1.

The reproducing operation is performed by supplying a current pulse to a recording bit 27 of the recording layer 22 and detecting a resistance value of the recording bit 27. However, the current pulse should have a so small value that would not cause a change in resistance of the material included in the recording bit 27 of the recording layer 22.

For example, a read current (current pulse) generated by a sense amplifier S/A is supplied to the recording bit 27 from the probe 24, and a resistance value of the recording bit 27 is measured by the sense amplifier S/A.

With the material according to the embodiment illustrated in FIG. 1, a difference in resistance value between set and reset states can be provided to be equal to or greater than 10³Ω.

Note that in the reproducing operation, scanning the top of the recording medium with the probes 24 allows for continuous reproduction.

An erase (reset) operation is performed by Joule-heating the recording bit 27 of the recording layer 22 with a mass current pulse to promote an oxidization-reduction reaction in the recording bit 27. Alternatively, such a pulse may be applied that provides a potential difference opposite to that in the set operation.

The erase operation may be performed for each recording bit 27, or may be performed by a plurality of recording bits 27 or on a block-by-block basis.

(Using Recording Part of FIG. 4)

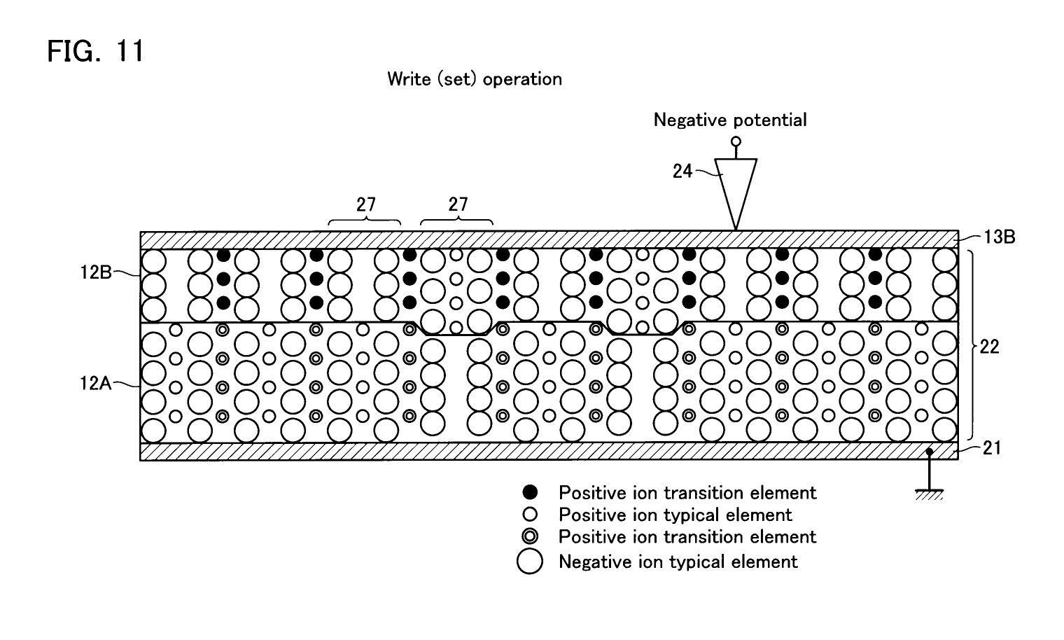

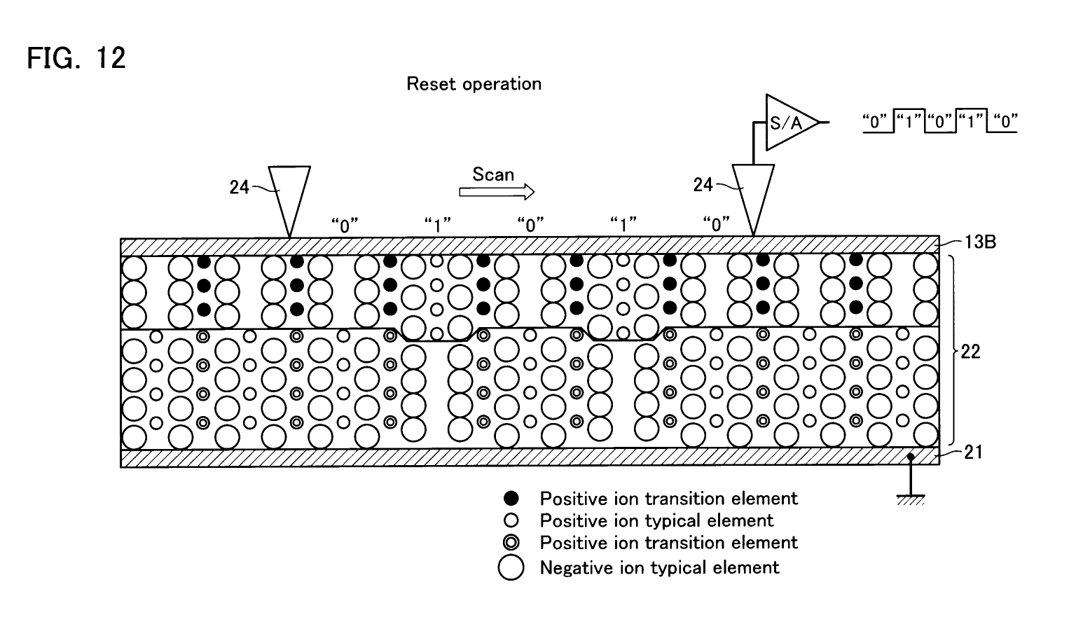

Referring now to FIGS. 11 and 12, recording/reproducing operations using the recording part of FIG. 4 will be described below.

FIG. 11 is a schematic diagram illustrating a state established at the time of recording.

Firstly, as illustrated in FIG. 11, such a state is established in which a potential of a probe 24 is relatively low compared to that of the electrode layer 21. Assuming that the electrode layer 21 is at a fixed potential, for example, a grounding potential, a negative electric potential may be applied to the probe 24.

At this point, some of the A ions in the first compound layer (anode side) 12A of the recording layer 22 travel through a crystal to be accommodated in cavity sites of the second compound (cathode side) 12B. Accordingly, the valence of the A ions in the first compound layer 12A increases, while the valence of the A ions in the second compound layer 12B decreases. As a result, conductive carriers are produced in the crystals of the first compound layer 12A and the second compound layer 12B, and both carriers have electrical (recording) is completed.

Meanwhile, if the positional relationship between the first compound layer 12A and the second compound layer 12B is inverted for the recording operation, a set operation may also be performed with a potential of a probe 24 being relatively low compared to that of the electrode layer 21.

FIG. 12 is a schematic diagram illustrating a state established at the time of reproducing.

A reproducing operation is performed by supplying a current pulse to the recording bit 27 and detecting a resistance value of the recording bit 27. However, the current pulse should have a so small value that would not cause a change in resistance of the material included in the recording bit 27.

For example, a read current (current pulse) generated by a sense amplifier S/A is supplied from a probe 24 to the recording layer (recording bit) 22, and a resistance value of the recording bit is measured by the sense amplifier S/A. The above-mentioned new material allows a difference in resistance value between set and reset states to be 10³Ω or more.

Note that the reproducing operation may be performed continuously by means of scanning of the probes 24.

A reset operation (erasing) may be achieved by promoting action of A ions attempting to return into the first compound layer 12A from cavity sites in the second compound layer 12B, by means of a Joule heat generated by supplying a mass current pulse to the recording layer (recording bit) 22 as well as the residual heat. Alternatively, such a pulse may be applied that provides a potential difference opposite to that in the set operation.

The erase operation may be performed for each recording bit 27, or may be performed by a plurality of recording bits 27 or on a block-by-block basis.

As described above, the probe memory according to this embodiment may achieve higher recording density and lower power consumption than those provided by currently available hard disks or flash memory.

When using the recording layer with the recording parts of FIGS. 4 and 5 for the recording layer 22, larger voltage margins and thus more stable operations may be achieved as compared with the recording layer of FIG. 1.

(Method of Manufacturing Probe Memory of FIG. 6)

A method of manufacturing the probe memory illustrated in FIG. 6 will now be described below.

A substrate 20 is provided as a disk made of glass, having a diameter of about 60 mm and a thickness of about 1 mm. An electrode layer 21 is formed on this substrate 20 by vapor deposition of Pt (platinum) to a thickness of about 500 nm.

On the electrode layer 21, film formation is first performed with an RF power supply whose power is adjusted to provide (110) orientation, by means of a target whose composition is adjusted so that TiN is deposited. Then, RF magnetron sputtering is carried out in an atmosphere of 95% of Ar (argon) and 5% of O₂ (oxygen) at temperatures between 300 to 600 degrees Centigrade, by means of a target whose composition is adjusted so that Mn_{0.8}Al_{2.1}O₄ is deposited. As a result, Mn_{0.8}Al_{2.1}O₄ having a thickness of about 10 nm is formed which is a part of the recording layer 22.

Subsequently, TiN having a thickness of about 3 nm is formed on Mn_{0.8}Al_{2.1}O₄ by RF magnetron sputtering.

Finally, a protection layer 13B is formed on the recording layer 22, after which a recording medium as illustrated in FIG. 6 is completed.

[Application 2: Crosspoint-Type Semiconductor Memory]

(Crosspoint-Type Semiconductor Memory Configuration)

Crosspoint-type semiconductor memory in which the recording parts of FIGS. 1 and 4 are implemented will now be described below.

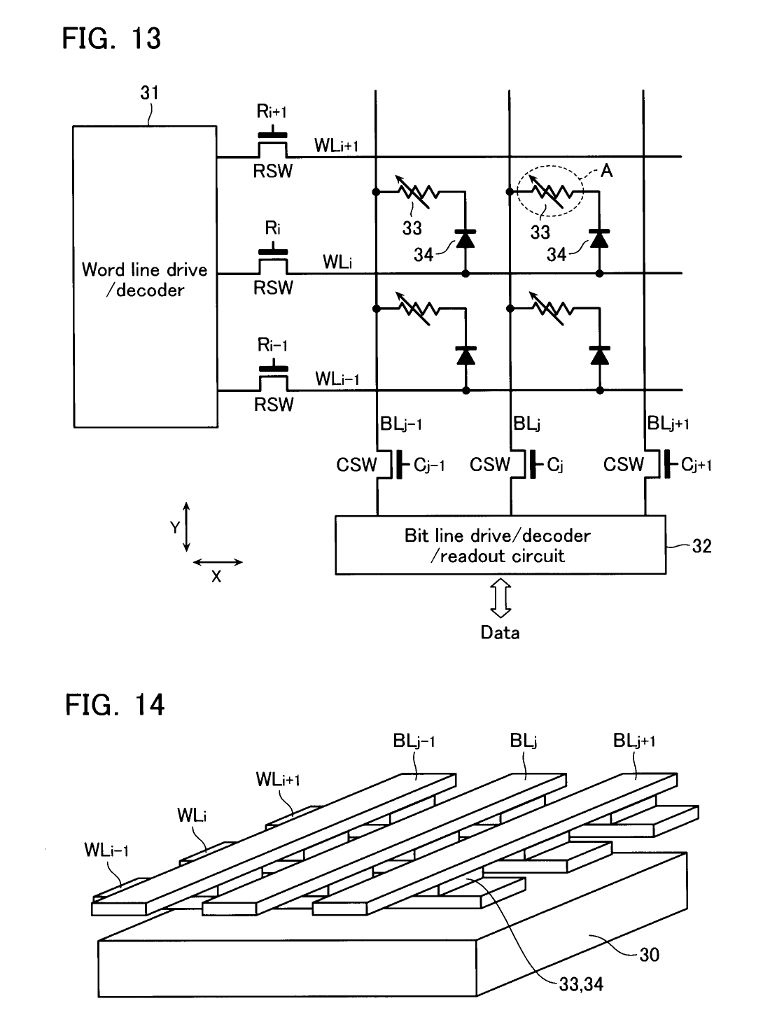

FIG. 13 is a schematic diagram illustrating semiconductor memory.

This semiconductor memory comprises word lines WLi−1, WLi, and WLi+1 that are first wirings extending in the X direction, and bit lines BLj−1, BLj, and BLj+1 that are second wirings extending in the Y direction.

One end of each of the word lines WLi−1, WLi, and WLi+1 is connected to a word line drive/decoder 31 via a MOS transistor RSW corresponding to a selection switch. On the other hand, one end of each of the bit lines BLj−1, BLj, and BLj+1 is connected to a bit line drive/decoder/readout circuit 32 via a MOS transistor CSW corresponding to a selection switch.

Selection signals Ri−1, Ri, and Ri+1 are input to the gates of the three MOS transistors RSW for selecting the word lines WLi−1, WLi, and WLi+1 (rows), respectively. On the other hand, selection signals Ci−1, Ci, and Ci+1 are input to the gates of the three MOS transistors CSW for selecting the bit lines BLj−1, BLj, and BLj+1 (columns), respectively.

Memory cells 33 are arranged at respective intersections between the word lines WLi−1, WLi, WLi+1 and the bit lines BLj−1, BLj, BLj+1. This is a so-called cross-point type cell array structure.

Diodes 34 are added to the memory cells 33 that are rectifier elements for preventing a Sneak current during recording/reproducing operations.

FIG. 14 is a schematic diagram illustrating a memory cell array part of the semiconductor memory illustrated in FIG. 13.

Word lines WLi−1, WLi, WLi+1 and bit lines BLj−1, BLj, BLj+1 are arranged on a semiconductor chip 30. Memory cells 33 and diodes 34 are arranged at respective intersections between these lines. Note that barrier layers (not illustrated) may be provided between the diodes 34 and the word lines WL.

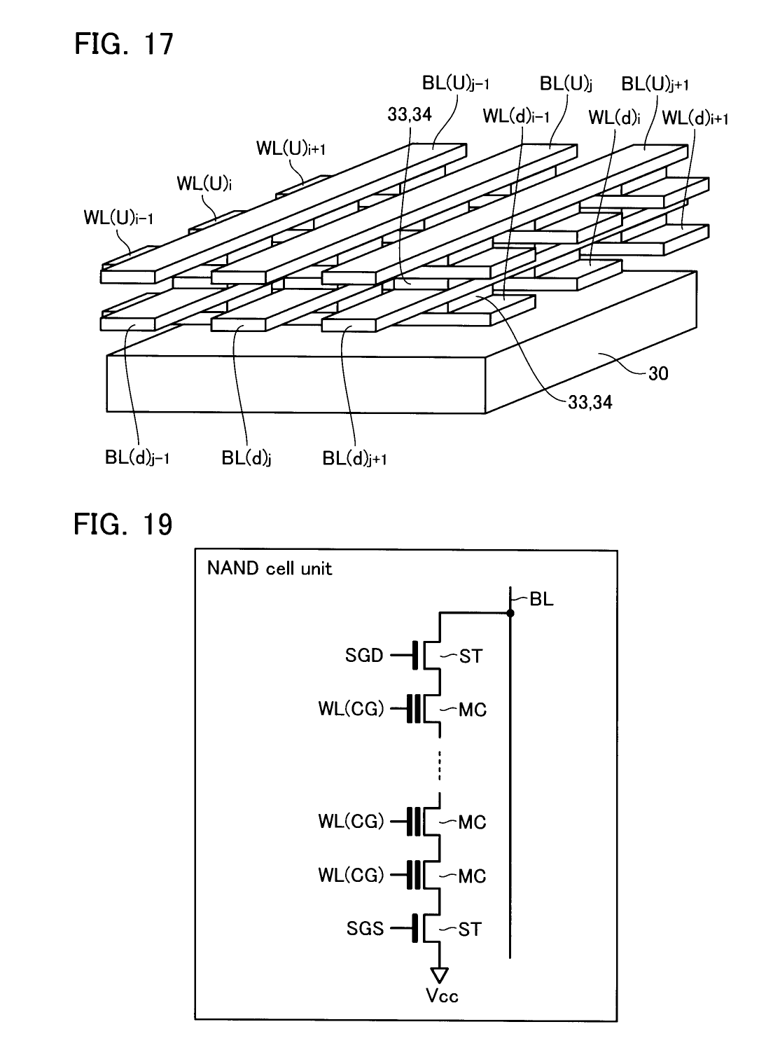

A feature of this cross-point type cell array structure is that it is advantageous for high integration because there is no need to individually connect a MOS transistor to a memory cell 33. For example, as illustrated in FIGS. 16 and 17, it is also possible to laminate memory cells 33 to provide a memory cell array with a three-dimensional structure.

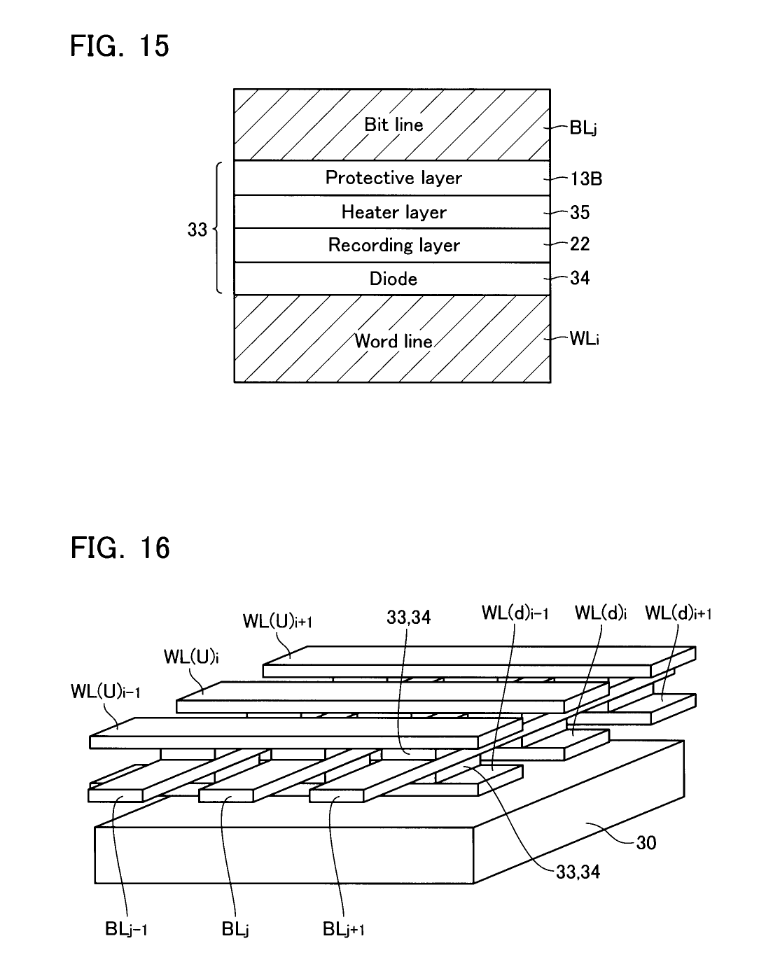

For example, as illustrated in FIG. 15, a memory cell 33 having the recording part illustrated in FIGS. 1 to 3 includes a stuck structure of a recording layer 22, a protection layer 13B, and a heater layer 35. Each memory cell 33 stores 1-bit data. On the other hand, a diode 34 is arranged between a word line WL and a memory cell 33. As mentioned before, barrier layers (not illustrated) may be provided between the diodes 34 and the word lines WL.

FIGS. 16 and 17 are schematic diagrams illustrating other examples of the memory cell array.

In the case of FIG. 16, the word lines WLi−1, WLi, and WLi+1 extending in the X direction are provided above and below the bit lines BLj−1, BLj, and BLj+1 extending in the Y direction. In addition, memory cells and diodes 34 are disposed at respective intersections between the bit lines BL and the word lines WL. This means that the bit lines BL are shared by respective memory cells 33 and diodes 34 located above and below them. Note that barrier layers (not illustrated) may be provided between the diodes 34 and the word lines WL (d), between the diodes 34 and the bit lines BL, and so on.

The specific example illustrated in FIG. 17 involves a structure in which the bit lines BLj−1, BLj, and BLj+1 extending in the Y direction and the word lines WLi−1, WLi, and WLi+1 extending in the X direction are alternately laminated. In addition, memory cells 33 and diodes 34 are disposed at respective intersections between the bit lines BL and the word lines WL. Note that barrier layers (not illustrate) may be provided between the diodes 34 and the word lines WL (d), between the diodes 34 and the bit lines BL (d), between the diodes 34 and the word lines WL (u), and between the diodes 34 and the word lines WL (u).

The lamination structure as illustrated in FIGS. 16 and 17 allows for higher recording density.

(Recording/Reproducing Operations of Crosspoint-Type Semiconductor Memory)

Referring now to FIGS. 13 to 15, recording/reproducing operations of the semiconductor memory using the recording layer of this embodiment will be described below.

It is assumed here that a memory cell 33 enclosed by a dotted line A in FIG. 13 is selected, and recording/reproducing operations are performed thereon.

(Operation Using Recording Part of FIG. 1)

Description is first made on recording/reproducing operations when using the recording part of FIG. 1.

A recording operation (set operation) may be achieved by applying voltage to a selected memory cell 33, and supplying a current pulse to the memory cell 33 by means of a potential gradient generated in the memory cell 33. Thus, for example, such a state is established in which a potential of a word line WLi is relatively low compared to that of a bit line BLj. Assuming that the bit line BLj is at a fixed potential, for example, a grounding potential, a negative potential may be applied to the word line WLi.

At this point, in the selected memory cell 33 enclosed by the dotted line A, some of A ions move to the side of the word line (cathode) WLi, and the A ions in the crystal decrease relative to the X ions. In addition, the A ions moved to the side of the word line WLi precipitate as a metal upon receipt of electrons from the word line WLi.

The X ions become excessive in the selected memory cell 33 enclosed by the dotted line A, which results in an increase of the valence of the A ions or M ions in the crystal. Namely, the selected memory cell 33 enclosed by the dotted line A has electron conductivity due to carrier implantation caused by a phase change. Consequently, the recording operation (set operation) is completed.

Note that at the time of recording, it is desirable to bias all of the unselected word lines WLi−1, WLi+1, and unselected bit lines BLj−1, BLj+1 to the same potential.

In addition, during a standby state before recording, it is desirable to precharge all of the word lines WLi−1, WLi, and WLi+1 as well as all of the bit lines BLj−1, BLj, and BLj+1.

A current pulse for recording may also be generated by establishing such a state in which a potential of the word line WLi is relatively high compared to that of the bit line BLj.

A reproducing operation is performed by supplying a current pulse to the selected memory cell 33 enclosed by the dotted line A, and detecting a resistance value of the memory cell 33. However, the current pulse should have a so small value that would not cause a change in resistance of the material included in the memory cell 33.

For example, a read current (current pulse) generated by a readout circuit is supplied from the bit line BLj to the memory cell 33 enclosed by the dotted line A, and a resistance value of the memory cell 33 is measured by the readout circuit. The above-mentioned new material allows a difference in resistance value between set and reset states to be 10³Ω or more.

An erase (reset) operation is performed by Joule-heating the selected memory cell 33 enclosed by the dotted line A with a mass current pulse to promote an oxidization-reduction reaction in the memory cell 33.

(Operation Using Recording Part of FIG. 4)

Description is now made on recording/reproducing operations when using the recording part of FIG. 4.

A recording operation (set operation) may be achieved by applying voltage to a selected memory cell 33, and supplying a current pulse to the memory cell 33 by means of a potential gradient generated in the memory cell 33. Thus, for example, such a state is established in which a potential of a word line WLi is relatively low compared to that of a bit line BLj. Assuming that the bit line BLj is at a fixed potential (e.g., a grounding potential), a negative potential may be applied to the word line WLi.

At this point, in the selected memory cell 33 enclosed by the dotted line A, some of A ions in the first compound 12A move to the cavity sites of the second compound 12B. Thus, the valence of A ions or M2 ions in the second compound 12B decreases, while the valence of A ions or M1 ions in the first compound 12A increases. As a result, conductive carriers are produced in the crystals of the first and second compounds 12A and 12B, and both carriers have electrical conductivity. Consequently, the set operation (recording) is completed. Note that at the time of recording, it is desirable to bias all of the unselected word lines WLi−1, WLi+1, and unselected bit lines BLj−1, BLj+1 to the same potential.

In addition, during a standby state before recording, it is desirable to precharge all of the word lines WLi−1, WLi, and WLi+1 as well as all of the bit lines BLj−1, BLj, and BLj+1.

A current pulse may also be generated by establishing such a state in which a potential of the word line WLi is relatively high compared to that of the bit line BLj.

A reproducing operation is performed by supplying a current pulse to the selected memory cell 33 enclosed by the dotted line A, and detecting a resistance value of the memory cell 33. However, the current pulse should have a so small value that would not cause a change in resistance of the material included in the memory cell 33.

For example, a read current (current pulse) generated by a readout circuit is supplied from the bit line BLj to the memory cell 33 enclosed by the dotted line A, and a resistance value of the memory cell 33 is measured by the readout circuit. The above-mentioned new material allows a difference in resistance value between set and reset states to be 10³Ω or more.

A reset (erase) operation may be achieved by promoting action of A ion elements attempting to return into the first compound 12A from the cavity sites in the second compound 12B, by means of a Joule heat generated by supplying a mass current pulse to the selected memory cell 33 enclosed by the dotted line A as well as the residual heat.

As described above, the semiconductor memory of this embodiment may achieve higher recording density and lower power consumption than those provided by currently available hard disks or flash memory.

Using the recording part of FIGS. 4 and 5 for the recording layer 22 facilitates ion transfer and allows for more stable existence of diffused ion elements. This may result in a reduction in power consumption required for resistance change, improving heat stability. In addition, switching is performed only in the first compound layer by using a material with conductivity for the second compound layer before and after the operation. This ensures a sufficient level of disturbance resistance, improving operational stability.

[Application 3: Flash Memory]

Description is now made on flash memory in which the recording layers of FIGS. 1 and 4 are implemented.

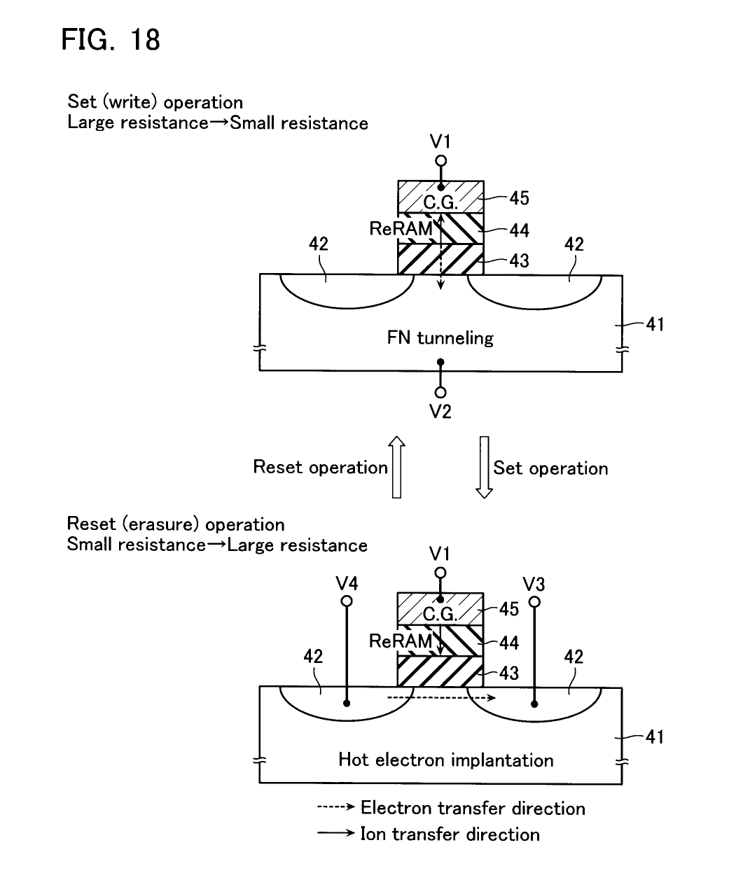

FIG. 18 is a schematic diagram illustrating a memory cell of this flash memory.

This memory cell includes MIS (Metal Insulator Semiconductor) transistors.

Diffusion layers 42 are formed in a surface region of a semiconductor substrate 41. A gate insulation layer 43 is formed on a channel region between the diffusion layers 42. Formed on the gate insulation layer 43 is a recording layer (ReRAM: Resistive RAM) according to this embodiment. Formed on the recording part 44 is a control gate electrode 45.

The semiconductor substrate 41 maybe a well region. In addition, the semiconductor substrate 41 and the diffusion layers 42 have opposite conductivity types to each other. The control gate electrode 45 becomes a word line which includes, e.g., conductive polysilicon.

The recording layer 44 is formed by the material included in the recording layers 12 as illustrated in FIGS. 1, 4, and 5.

Referring now to FIG. 18, a basic operation of the memory cell will be described below.

A set (write) operation is performed by providing the control gate electrode 45 with a potential V1, while the semiconductor substrate 41 with a potential V2.

While a difference between the potentials V1 and V2 should be large enough for the recording layer 44 to change its phase or resistance, there is no specific restriction on the direction of the potentials.

That is, any of V1>V2 and V1<V2 is possible.

For example, assuming that the recording layer 44 is an insulator (large resistance) in its initial state (reset state), the gate insulation layer 43 would virtually be thicker, and hence the threshold voltage of the memory cell (MIS transistor) becomes higher.

From this state, when the recording layer 44 changes to a conductor (small resistance) by application of the potentials V1 and V2, the gate insulation layer 43 would virtually be thinner, and hence the threshold voltage of the memory cell (MIS transistor) becomes lower.

While the potential V2 is applied to the semiconductor substrate 41, it may alternatively be transferred from the diffusion layers 42 to the channel region in the memory cell.

A reset (erase) operation is performed by applying a potential V1′ to the control gate electrode 45, a potential V3 to one of the diffusion layers 42, and a potential V4 (<V3) to the other of the diffusion layers 42.

The potential V1′ is set to a value greater than a threshold voltage of the memory cell in a set state.

At this point, the memory cell turns on, electrons flow toward the one diffusion layer 42 from the other, and hot electrons are generated. Since the hot electrons are implanted into the recording layer 44 via the gate insulation layer 43, the temperature of the recording layer 44 rises.

As a result, the gate insulation layer 43 virtually becomes thicker as the recording layer 44 changes from a conductor (small resistance) to an insulator (high resistance), increasing the threshold voltage of the memory cell (MIS transistor).

In this way, the threshold voltage of the memory cell can be changed based on a principle similar to the flash memory. Therefore, flash memory technologies may be used to implement the information recording and reproducing apparatus according to examples of this embodiment.

(NAND-Type Flash Memory)

The memory cell illustrated in FIG. 18 may be used to configure NAND-type flash memory.

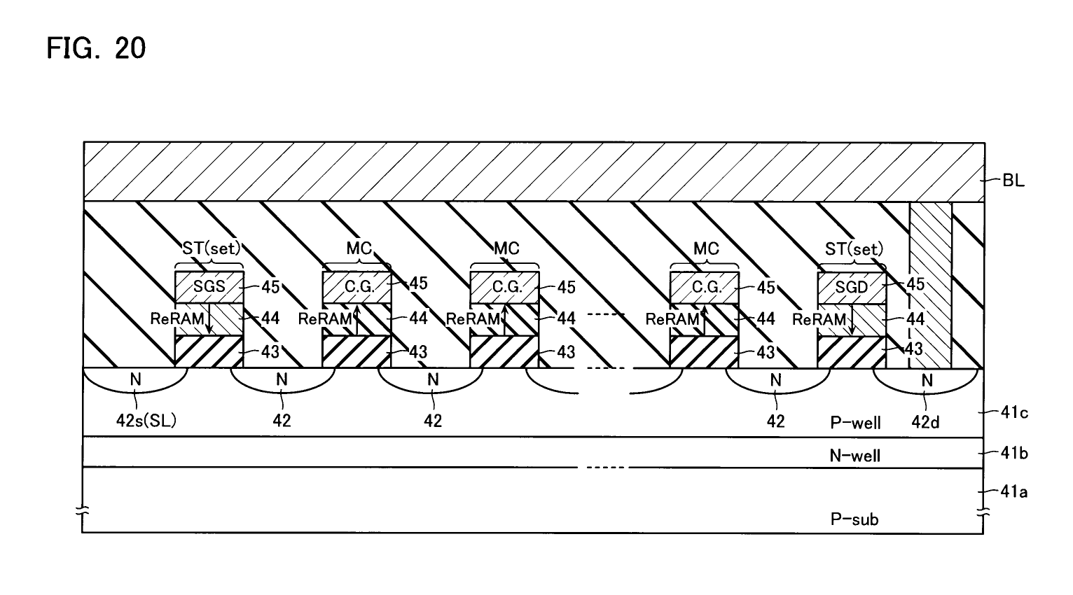

FIG. 19 is a circuit diagram of a NAND cell unit included in the NAND-type flash memory; and FIG. 20 is a schematic diagram illustrating a structure of the NAND cell unit.

As illustrated in FIG. 20, an N-type well region 41b and a P-type well region 41c are formed in a P-type semiconductor substrate 41a. Formed in the P-type well region 41c is a NAND cell unit according to an example of this embodiment.

The NAND cell unit comprises a NAND string including a plurality of memory cells MC connected in series, and two select gate transistors ST connected to each end of the NAND string.

The memory cells MC and the select gate transistors ST have the same structure. Specifically, each of them includes N-type diffusion layers 42, a gate insulation layer 43 on a channel region between the N-type diffusion layers 42, a recording layer (ReRAM) 44 on the gate insulation layer 43, and a control gate electrode 45 on the recording layer 44.

The states (insulator/conductor) of the recording layers 44 of the memory cells MC can be changed according to the above-mentioned basic operation. In contrast, the recording layers 44 of the select gate transistors ST are fixed at a set state, i.e., to be a conductor (small resistance).

One of the select gate transistors ST is connected to a source line SL (third wiring), while the other connected to a bit line BL (second wiring).

It is intended that all of the memory cells in the NAND cell unit are in reset states (large resistance) before a set (write) operation.

A set (write) operation is sequentially performed on the memory cells MC one at a time, in order of those located at the side of the source line SL before those at the side of the bit line BL.

V1 (plus potential) is applied to a selected word line (control gate electrode) WL (first wiring) as a write potential, while Vpass is applied to unselected word lines WL as a transfer potential (at which memory cells MC turn on).

When the select gate transistor ST at the side of the source line SL is turned off and the select gate transistor ST at the side of the bit line BL is turned on, program data is transferred from the bit line BL to the channel region of a selected memory cell MC.

For example, when the program data is “1”, a write inhibit potential (e.g., a potential on the order of V1) is transferred to the channel region of the selected memory cell MC to prevent the resistance value of the recording layer 44 of the selected memory cell MC from changing from high to low.

In addition, when the program data is “0”, V2 (<V1) is transferred to the channel region of the selected memory cell MC to change the resistance value of the recording layer 44 of the selected memory cell MC from high to low.

In a reset (erase) operation, for example, V1′ is applied to all of the word lines (control gate electrodes) WL to turn on all of the memory cells MC in the NAND cell. In addition, the two select gate transistors ST are turned on, V3 is applied to the bit line BL, and V4 (<V3) is applied to the source line SL.

At this point, hot electrons are implanted into the recording layers 44 of all of the memory cells MC in the NAND cell unit. Accordingly, a reset operation is performed on all of the memory cells MC in the NAND cell unit at a time.

In a read operation, a read potential (plus potential) is applied to a selected word line (control gate electrode) WL, while such a potential is applied to the unselected word lines (control gate electrodes) WL that causes the memory cells MC to turn on whenever it is applied to the memory cells MC, whether data is “0” or “1”.

In addition, the two select gate transistors ST are turned on, and a read current is supplied to the NAND string.

Since the selected memory cell MC turns on or off upon application of a read potential depending on the value of data stored therein, data can be read by, for example, detecting a change in the read current.

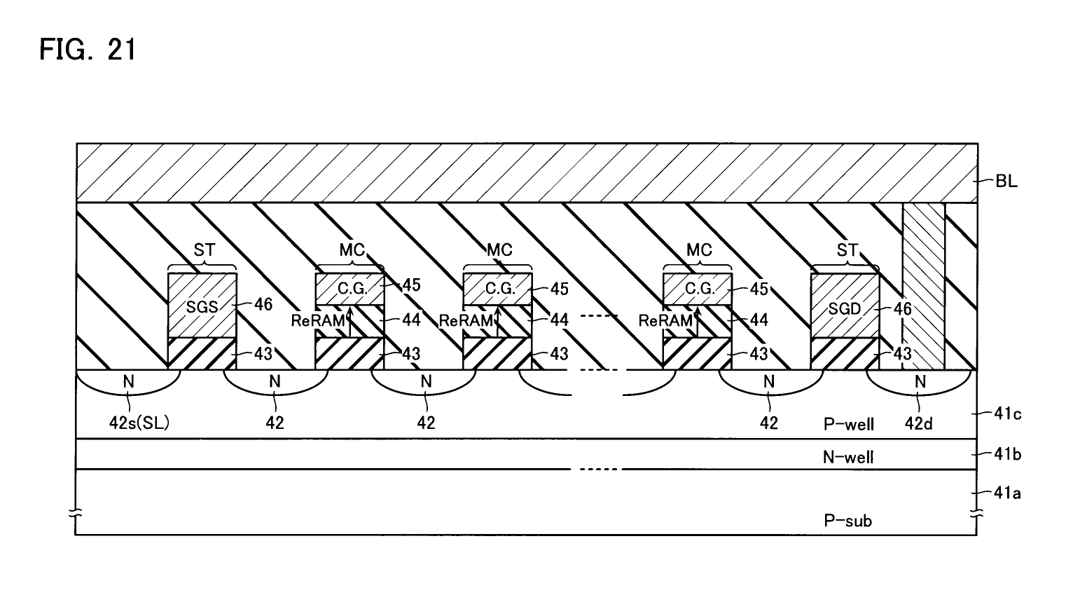

While the select gate transistors ST have the same structure as the memory cells MC within the structure of FIG. 21, the select gate transistors ST may also be normal MIS transistors without forming recording layers, for example, as illustrated in FIG. 21.

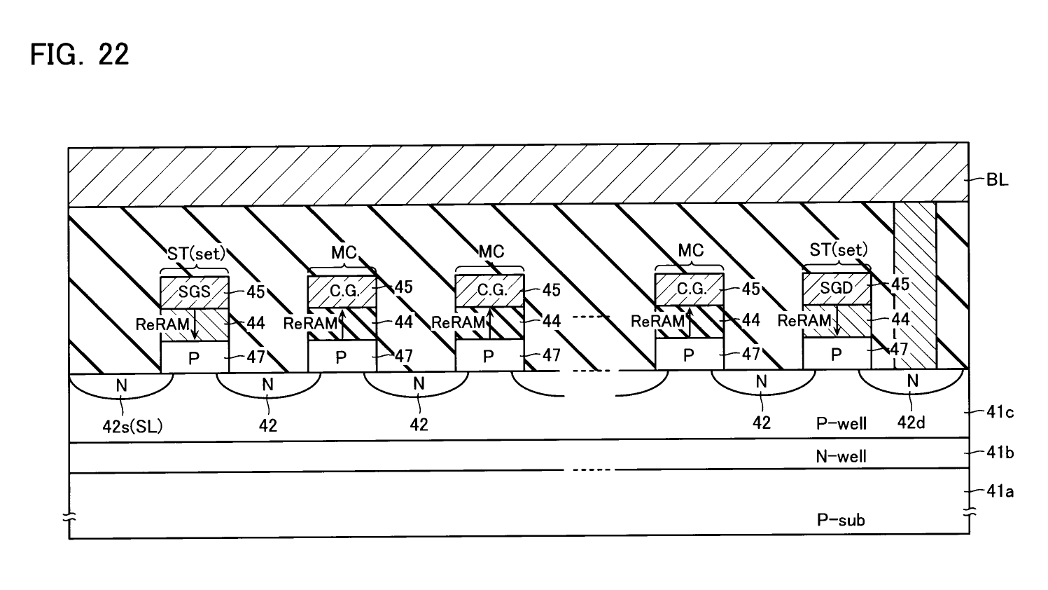

FIG. 22 is a schematic diagram illustrating a variation of the NAND-type flash memory.

This variation has such a structure where the gate insulation layers of a plurality of memory cells MC included in the NAND string are replaced with P-type semiconductor layers 47.

As integration proceeds and memory cells MC are getting more miniaturized, the P-type semiconductor layers 47 would be filled up with depletion layers without application of voltage.

In a set (write) operation, a plus write potential (e.g., 4.5V) is applied to the control gate electrode 45 of the selected memory cell MC, and a plus transfer potential (e.g., 1V) is applied to the control gate electrodes 45 of the unselected memory cells MC.

At this point, the surface portions of the P-type well region 41c corresponding to a plurality of memory cells MC in the NAND string are inverted from P-type to N-type to form channels.

Therefore, as described above, a set operation may be performed by turning on the select gate transistor ST at the side of the bit line BL, and transferring program data “0” from the bit line BL to the channel region of the selected memory cell MC.

A reset (erase) operation may be performed on all of the memory cells MC included in the NAND string at a time by, for example, applying a negative erase potential (e.g., −4.5V) to all of the control gate electrodes 45 and a grounding potential (0V) to the P-type well region 41c and the P-type semiconductor layers 47.

In a read operation, a positive read current (e.g., 0.5V) is applied to the control gate electrode 45 of the selected memory cell MC, and such a transfer potential (e.g., 1V) is applied to the control gate electrodes 45 of the unselected memory cells MC that causes the memory cells MC to turn on whenever it is applied to the memory cells MC, whether data is “0” or “1”.

However, it is assumed that a threshold voltage Vth “1” of a memory cell MC in “1” state is within a range of 0V<Vth “1”<0.5V, and a threshold voltage Vth “0” of a memory cell MC in “0” state is within a range of 0.5V<Vth “0”<1V.

In addition, the two select gate transistors ST are turned on, and a read current is supplied to the NAND string.

Under these conditions, the amount of current flowing through the NAND string varies depending on the value of data stored in the selected memory cell MC.

As such, data may be read by detecting a change in the amount of current.

Note that in this variation, it is desirable that the amount of hole doping of each P-type semiconductor layer 47 is greater than that of the P-type well region 41c, and that a Fermi level of each P-type semiconductor layer 47 is deeper than that of the P-type well region 41c by on the order of 0.5V.

This is to ensure that when a plus potential is applied to the control gate electrode 45, inversion from P-type to N-type starts from the surface portions of the P-type well region 41c between N-type diffusion layers 42, and channels are formed successfully.

In this way, for example, at the time of writing, channels of unselected memory cells MC are formed only at the interfaces between the P-type well region 41c and P-type semiconductor layers 47. In turn, at the time of reading, channels of a plurality of memory cells MC in the NAND string are formed only at the interfaces between the P-type well region 41c and P-type semiconductor layers 47.

This means that even if the recording layers 44 of the memory cells MC are conductors (in set states), the diffusion layers 42 and the control gate electrode 45 cannot be short-circuited.

(NOR-Type Flash Memory)

The memory cell illustrated in FIG. 18 may also be used to configure NOR-type flash memory.

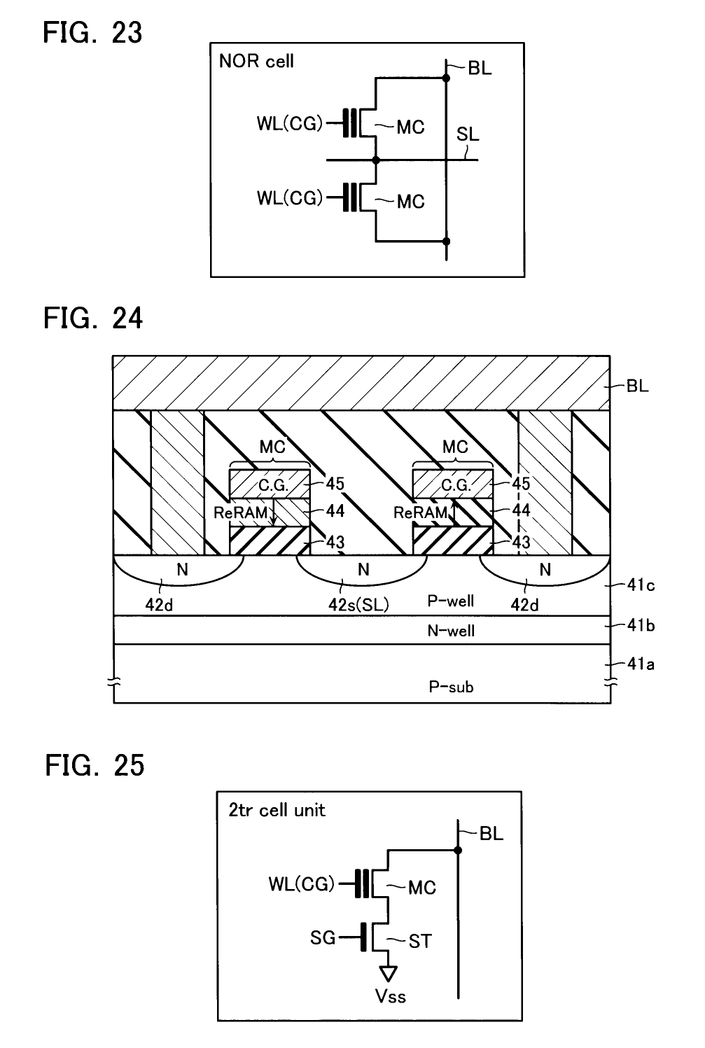

FIG. 23 is a circuit diagram of a NOR cell unit; and FIG. 24 is a schematic diagram illustrating a structure of the NOR cell unit.

An N-type well region 41b and a P-type well region 41c are formed in a P-type semiconductor substrate 41a. Formed in the P-type well region 41c are NOR cells according to an example of this embodiment.

Each NOR cell includes one memory cell (MIS transistor) MC connected between a bit line BL and a source line SL.

Each memory cell MC includes N-type diffusion layers 42, a gate insulation layer 43 on a channel region between the N-type diffusion layers 42, a recording layer (ReRAM) 44 on the gate insulation layer 43, and a control gate electrode 45 on the recording layer 44. The state (insulator/conductor) of the recording layer 44 of each memory cell MC can be changed according to the above-described basic operation.

(2-Transistor Type Flash Memory)

The memory cell illustrated in FIG. 18 may also be used to configure 2-transistor type flash memory.

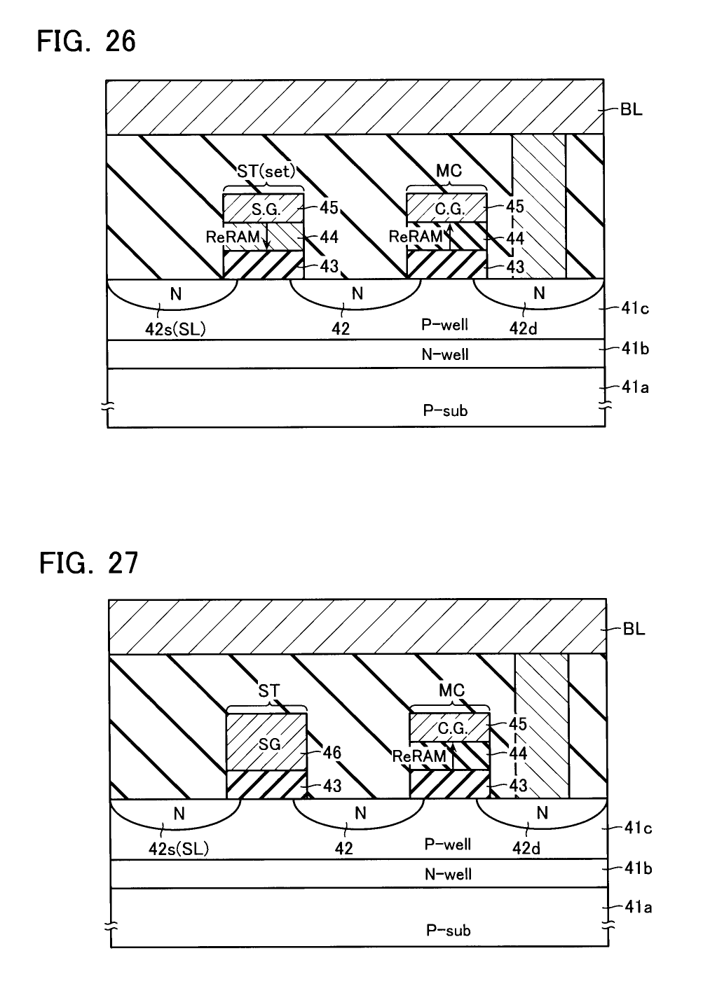

FIG. 25 is a circuit diagram of a 2-transistor type cell unit; and FIG. 26 is a schematic diagram illustrating a structure of the 2-transistor type cell unit.

The 2-transistor type cell unit has been recently developed as a new cell structure having both features of the NAND cell unit and the NOR cells.

An N-type well region 41b and a P-type well region 41c are formed in the P-type semiconductor substrate 41a. The 2-transistor type cell unit according to an example of this embodiment is formed in the P-type well region 41c.

The 2-transistor type cell unit includes one memory cell MC and one select gate transistor ST connected in series.

The memory cell MC and the select gate transistor ST have the same structure. Specifically, each of them includes N-type diffusion layers 42, a gate insulation layer 43 on a channel region between the N-type diffusion layers 42, a recording layer (ReRAM) 44 on the gate insulation layer 43, and a control gate electrode 45 on the recording layer 44.

The state (insulator/conductor) of the recording layer 44 of the memory cell MC can be changed according to the above-described basic operation. In contrast, the recording layer 44 of the select gate transistor ST is fixed at a set state, i.e., to be a conductor (small resistance).

The select gate transistor ST is connected to a source line SL, while the memory cell MC is connected to a bit line BL.

The state (insulator/conductor) of the recording layer 44 of the memory cell MC can be changed according to the above-described basic operation.

While the select gate transistor ST has the same structure as the memory cell MC within the structure of FIG. 26, the select gate transistor ST may also be a normal MIS transistor without forming a recording layer, for example, as illustrated in FIG. 27.

In these types of flash memory, using the recording layers 12 of FIGS. 4 and 5 for the recording layers 44 facilitates ion transfer and allows for more stable existence of diffused ion elements. This may result in a reduction in power consumption required for resistance change, improving heat stability. In addition, switching is performed only in the first compound layer by using a material with conductivity for the second compound layer before and after the operation, ensuring a sufficient level of disturbance resistance. That is, operational stability is ensured.

[Other Applications]

In addition to the above-described applications, the materials and principles proposed by this embodiment may also be applied to other recording media, such as present hard disks or DVDs.

### Experimental Examples

Description is now made on experimental examples where some samples are prepared and a resistance difference between reset (erasing) and set (writing) states is evaluated.

A recording medium having the structure illustrated in FIG. 5 is used as a sample. Evaluation is made by using a pair of probes with a diameter of each distal end sharpened to 10 nm or less.

The pair of probes is brought into contact with the protection layer 13B, and write/erase operations are performed with one of the probes. The write operation is performed by, for example, applying a voltage pulse of 1V having a pulse width of 10 ns to the recording layer 22. The erase operation is performed by, for example, applying a voltage pulse of 0.2V having a pulse width of 100 ns to the recording layer 22.

In addition, a read operation is performed between the write and erase operations by using the other of the pair of probes. The read operation is performed by applying a voltage pulse of 0.1V having a pulse width of 10 ns to the recording layer 22, and measuring a resistance value of the recording layer (recording bit) 22.

### First Experimental Example

Specifications for samples of a first experimental example are as follows:

The recording layer 22 has a lamination structure including Mn_{0.3}Al_{2.4}O₄ having a thickness of about 10 nm and TiN having a thickness of about 5 nm.

In this case, it has been found that the reset voltage is about +0.5V and the set voltage is about +3.5V during unipolar operation, while the reset voltage is about +0.5V and the set voltage is about −3.5V during bipolar operation.

### Comparative Example

Specifications for samples of a comparative example are as follows:

The recording layer 22 has only a lamination structure including Mn_{1.2}Al_{1.8}O₄ having a thickness of about 10 nm and TiO₂ (titanium oxide) having a thickness of about 5 nm.

In this case, it has been found that the reset voltage is about +0.5V and the set voltage is about +1.5V during unipolar operation, while the reset voltage is about +0.5V and the set voltage is about −1.5V during bipolar operation.

As can be seen from the above, with the samples of the first experimental example, larger voltage margins are provided during unipolar and bipolar operations. In contrast, according to the comparative example, smaller voltage margins are provided during unipolar and bipolar operations. This means that this embodiment offers a significant reduction in malfunction probability during set/reset operations.

[Conclusion]

As can be seen from the above, according to this embodiment, an information record (write) operation is performed only at a site (recording unit) to which an electric field is applied. Consequently, information can be recorded in a very small region with extremely small power consumption. This allows concurrent and parallel processing of a large number of cells, achieving very high speed operation per chip.

On the other hand, an information erase operation is performed by applying heat to the recording layer 12. However, the materials proposed by this embodiment allows for erasing with small power consumption with little structural change of oxide. An erase operation may also be performed by applying an electric field opposite to that used in the recording operation. Since the latter case involves less energy loss of thermal diffusion, erasing may be performed with smaller power consumption.

In addition, according to this embodiment, a conductor portion is formed within an insulator after a write operation. Consequently, current flows intensively through the conductor portion during a read operation, achieving a recording principle with extremely high sensing efficiency.

Furthermore, according to this embodiment, a combination of positive ions being easy to transfer and transition element ions keeping a host structure stable allows for repetitive and stable record erasure.

Note that if the recording layer of FIG. 4 or 5 is used, a larger voltage margin may be provided, and hence the malfunction probabilities may be significantly reduced.

As can be seen from the above, this embodiment may provide an information recording and reproducing apparatus that provides, despite its extremely simple mechanism, a high recording density as well as stable, high speed operations that cannot be achieved by the conventional art. To this extent, the inventive apparatus has significant industrial advantages as a next generation technology that would push back the limits of recording density of currently available non-volatile memory.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

While the terms “set” and “reset” have been defined in the context of an initial state being one immediately after film formation in the above-described embodiments, this definition is arbitrary. In addition, various other embodiments may include any combination of the components disclosed in the embodiments described above, as deemed appropriate. For example, some of the components of the embodiments may be omitted, or components of different embodiments can be combined in any appropriate manner.

What is claimed is:

1. An information recording and reproducing apparatus comprising:
a memory cell including a recording layer operative to change in a reversible manner between a first state and a second state, the first state having a certain resistance value upon application of a voltage pulse, and the second state having a resistance value higher than that of the first state,
the recording layer including a first compound layer represented by a composition formula of AₓM_{y}X₄ (0.1≦x≦1.2, 2<y≦2.9),
the A being at least one element selected from a group of Mn (manganese), Fe (iron), Co (cobalt), Ni (nickel), and Cu (copper),
the M being at least one element selected from a group of Al (aluminum), Ga (gallium), Ti (titanium), Ge (germanium), and Sn (tin), and
the X being O (oxygen).

2. The information recording and reproducing apparatus according to claim 1, wherein
a material included in the recording layer has a spinel structure.

3. The information recording and reproducing apparatus according to claim 1, wherein
the A is Mn, the M is Al, and an Al/Mn ratio is equal to or greater than 2.

4. The information recording and reproducing apparatus according to claim 1, wherein
a relation between x and y of the composition formula AₓM_{y}X₄ is “2x+3y≦8”.

5. The information recording and reproducing apparatus according to claim 1, wherein
the recording layer includes a second compound layer laminated on the first compound layer and having a cavity site capable of accommodating an A ion element of the first compound.

6. The information recording and reproducing apparatus according to claim 5, wherein
the recording layer includes alternate lamination of the first compound layer and the second compound layer.

7. An information recording and reproducing apparatus comprising:
a first wiring extending in a first direction;
a second wiring extending in a second direction intersecting the first direction; and
a memory cell arranged at an intersection between the first and second wirings, and including a recording layer operative to change in a reversible manner between a first state and a second state, the first state having a certain resistance value upon application of a voltage pulse supplied via the first and second wirings, and the second state having a resistance value higher than that of the first state,
the recording layer including a first compound layer represented by a composition formula of AₓM_{y}X₄ (0.1≦x≦1.2, 2<y≦2.9),
the A being at least one element selected from a group of Mn (manganese), Fe (iron), Co (cobalt), Ni (nickel), and Cu (copper),
the M being at least one element selected from a group of Al (aluminum), Ga (gallium), Ti (titanium), Ge (germanium), and Sn (tin), and
the X being O (oxygen).

8. The information recording and reproducing apparatus according to claim 7, comprising:
a diode between the memory cell and the first wiring or the second wiring.

9. The information recording and reproducing apparatus according to claim 7, wherein
a material included in the recording layer has a spinel structure.

10. The information recording and reproducing apparatus according to claim 7, wherein
the A is Mn, the M is Al, and an Al/Mn ratio is equal to or greater than 2.

11. The information recording and reproducing apparatus according to claim 7, further comprising
a plurality of memory cell arrays laminated one upon another, each of the memory cell arrays including the first and second wirings as well as the memory cell.

12. An information recording and reproducing apparatus comprising:
a semiconductor substrate having a plurality of diffusion layers formed on a surface region there of and a channel region formed between the diffusion layers; and
a memory cell having a gate insulation layer formed on the channel region, a recording layer formed on the gate insulation layer, and a control gate electrode formed on the recording layer,
the memory cell having a recording layer operative to change in a reversible manner between a first state and a second state, the first state having a certain resistance value upon application of voltage, and the second state having a resistance value higher than that of the first state,
the recording layer including a first compound layer represented by a composition formula of AₓM_{y}X₄ (0.1≦x≦1.2, 2<y≦2.9),
the A being at least one element selected from a group of Mn (manganese), Fe (iron), Co (cobalt), Ni (nickel), and Cu (copper),
the M being at least one element selected from a group of Al (aluminum), Ga (gallium), Ti (titanium), Ge (germanium), and Sn (tin), and
the X being O (oxygen).

13. The information recording and reproducing apparatus according to claim 12, wherein
a material included in the recording layer has a spinel structure.

14. The information recording and reproducing apparatus according to claim 12, wherein
the A is Mn, the M is Al, and an Al/Mn ratio is equal to or greater than 2.

15. The information recording and reproducing apparatus according to claim 12, wherein
a relation between x and y of the composition formula AₓM_{y}X₄ is “2x+3y≦8”.

16. The information recording and reproducing apparatus according to claim 12, wherein
the recording layer includes a second compound layer laminated on the first compound layer and having a cavity site capable of accommodating an A ion element of the first compound.

17. The information recording and reproducing apparatus according to claim 12, comprising:
a first wiring connected to a control gate electrode of the memory cell,
wherein the recording layer of the memory cell is operative to change from the second state to the first state due to the voltage pulse applied between the first wiring and the semiconductor substrate.

18. The information recording and reproducing apparatus according to claim 12, comprising:
a first wiring connected to a control gate electrode of the memory cell; and
second and third wirings operative to supply voltages to two diffusion layers formed on the semiconductor substrate,
wherein the recording layer of the memory cell is operative to change from the first state to the second state, due to a voltage higher than a threshold voltage of the memory cell in the first state applied to the first wiring, and a potential difference applied between the second and third wirings to cause an electron to flow between the two diffusion layers.

19. The information recording and reproducing apparatus according to claim 12, comprising:
a NAND string including a plurality of the memory cells connected in series;
first and second select gate transistors connected to each end of the NAND string;
a second wiring connected to one end of the NAND string via the first select gate transistor; and
a third wiring connected to the other end of the NAND string via the second select gate transistor.

20. The information recording and reproducing apparatus according to claim 12, comprising:
a select gate transistor connected to one end of the memory cell;
a second wiring connected to the other end of the memory cell; and
a third wiring connected to the memory cell via the select gate transistor.
